(19) United States
(12) Patent Application Publication
(10) Pub. No.: US 2026/0162703 A1
(43) Pub. Date: Jun. 11, 2026

(54) MEMORY DEVICE AND OPERATION METHOD THEREOF

(71) Applicant: Samsung Electronics Co., Ltd., Suwon-si (KR)

(72) Inventors: KYUNG MIN LEE, Suwon-si (KR); Jae-Joon Kim, Seoul (KR); Jong-Ho Lee, Seoul (KR)

(73) Assignees: Samsung Electronics Co., Ltd., Suwon-si (KR); Seoul National University R&DB Foundation, Seoul (KR)

(21) Appl. No.: 19/220,176

(22) Filed: May 28, 2025

(30) Foreign Application Priority Data
Dec. 5, 2024 (KR) 10-2024-0179606

(51) Int. Cl. G11C 11/16

(52) U.S. Cl. CPC G11C 11/1675; G11C 11/1655; G11C 11/1657; G11C 11/1673

(57) ABSTRACT

A memory device includes a memory cell array comprising a weight cell array including a plurality of first weight cell pairs and a reference cell array including a plurality of reference cell pairs, and an analog-to-digital converter (ADC) connected to the plurality of first weight cell pairs and the plurality of reference cell pairs, and configured to output a signal representing a weighted sum of at least one weight value among a plurality of weight values stored in the plurality of first weight cell pairs and at least one reference value among a plurality of reference values stored in the plurality of reference cell pairs in response to activation of at least one corresponding first weight cell word line among a plurality of first weight cell word lines and at least one corresponding reference cell word line among a plurality of reference cell word lines during a read operation.

### CROSS-REFERENCE TO RELATED APPLICATION

This application claims priority to and the benefit of Korean Patent Application No. 10-2024-0179606 filed at the Korean Intellectual Property Office on Dec. 5, 2024, the entire contents of which are herein incorporated by reference.

### BACKGROUND

### (a) Field

The present disclosure relates to semiconductor memory, and more particularly, to a memory device and a method of operating the same.

### (b) Description of the Related Art

In general, the operating speed of the memory device and the computational speed of the processor are faster than the communication speed between the processor and the memory device. As artificial intelligence technology advances, various technologies are being studied to solve bottlenecks caused by communication speed in which memory devices perform some computational operations, is being studied.

The operation results of CiM memory can be converted into digital values as needed. Meanwhile, conventional analog-to-digital converters (ADC) have the problem of taking up a large area due to numerous comparators, capacitors, and compensation circuits.

### SUMMARY

The present disclosure attempts to provide a memory device and a method of operating the same capable of performing computational operations based on enhanced referencing.

According to an aspect of the present disclosure, a memory device includes a memory cell array comprising a weight cell array including a plurality of first weight cell pairs and a reference cell array including a plurality of reference cell pairs, and an analog-to-digital converter (ADC) connected to the plurality of first weight cell pairs and the plurality of reference cell pairs, and configured to output a signal representing a weighted sum of at least one weight value among a plurality of weight values stored in the plurality of first weight cell pairs and at least one reference value among a plurality of reference values stored in the plurality of reference cell pairs in response to activation of at least one corresponding first weight cell word line among a plurality of first weight cell word lines and at least one corresponding reference cell word line among a plurality of reference cell word lines during a read operation. Each weight value of the plurality of weight values has one of a first weight value and a second weight value different from the first weight value. Each reference value of the plurality of reference values has one of the first weight value and the second weight value.

According to an aspect of the present disclosure, a memory device includes a memory cell array including a weight cell array configured to store a plurality of weight values and a reference cell array configured to store a plurality of reference values, a sense amplifier configured to output an output signal based on the plurality of weight values and the plurality of reference values, a thermometer decoder configured to control a sequence of activating a plurality of word lines connected to the reference cell array based on a mode signal to determine when a level of the output signal is inverted, a binary counter configured to count a number of clocks until the level of the output signal is inverted and output a counting signal, and a flip-flop configured to store a weighted sum as a plurality of bits calculated based on the plurality of weight values based on the counting signal.

According to an aspect of the present disclosure, a method of operating a memory device includes a step of outputting a first weighted sum of a plurality of weight values stored in a plurality of weight cell pairs, a step of storing a sign of the first weighted sum in a flip-flop based on a signal level of the first weighted sum, wherein the sign of the first weighted sum is positive or negative, a step of performing reference scanning for a second weighted sum based on the sign of the first weighted sum by performing a read operation on both the plurality of weight cell pairs and a plurality of reference cell pairs storing a plurality of reference values, wherein the read operation is successively performed by increasing a number of reference cell pairs, among the plurality of reference cell pairs, which are activated, a step of determining the signal level of the second weighted sum in response to a sign of the second weighted sum changes from positive to negative or negative to positive, a step of outputting a counting signal of a binary counter, wherein the counting signal represents a number of the read operation successively performed, and a step of storing the second weighted sum as a plurality of bits in the flip-flop based on the counting signal, when the sign of the second weighted sum transitions positive to negative or negative to positive and a number of times the reference scanning is performed satisfy a predetermined condition.

### BRIEF DESCRIPTION OF THE DRAWINGS

FIG. 1 is a block diagram illustrating a memory system according to one embodiment of the present disclosure.

FIG. 2 is a block diagram illustrating a memory device according to one embodiment of the present disclosure.

FIG. 3 is a drawing for explaining a memory cell according to one embodiment of the present disclosure.

FIG. 4 is a drawing for explaining a memory cell pair according to one embodiment of the present disclosure.

FIG. 5 is a drawing for explaining a memory cell pair according to one embodiment of the present disclosure.

FIG. 6 is a drawing for explaining an output signal based on a weight value and an input signal according to a state of a memory cell pair according to one embodiment of the present disclosure.

FIG. 7 is a drawing for explaining the computation of a memory device according to one embodiment of the present disclosure.

FIG. 8 is a drawing for explaining a memory cell array according to one embodiment of the present disclosure.

FIG. 9 is a drawing for explaining a memory cell array according to one embodiment of the present disclosure.

FIG. 10 is a drawing for explaining the computation of a memory device according to one embodiment of the present disclosure.

FIG. 11 is a drawing for explaining a memory cell array according to one embodiment of the present disclosure.

FIG. 12 is a drawing for explaining a memory cell array according to one embodiment of the present disclosure.

FIG. 13 is a flowchart for explaining an operating method of a memory device according to one embodiment of the present disclosure.

FIG. 14 is a flowchart for explaining an operating method of a memory device according to one embodiment of the present disclosure.

FIG. 15 is a drawing for explaining an operating method of a memory device according to one embodiment of the present disclosure.

FIG. 16 is a flowchart for explaining an operating method of a memory device according to one embodiment of the present disclosure.

FIG. 17 is a drawing for explaining an operating method of a memory device according to one embodiment of the present disclosure.

FIG. 18 is a timing diagram for explaining an operating method of a memory device according to one embodiment of the present disclosure.

FIG. 19 is a block diagram illustrating a memory device according to one embodiment of the present disclosure.

FIG. 20 is a flowchart for explaining an operating method of a memory device according to one embodiment of the present disclosure.

FIG. 21 is a flowchart for explaining an operating method of a memory device according to one embodiment of the present disclosure.

FIG. 22 is a drawing for explaining an operating method of a memory device according to one embodiment of the present disclosure.

FIG. 23 is a drawing for explaining an operating method of a memory device according to one embodiment of the present disclosure.

FIG. 24 is a drawing for explaining an operating method of a memory device according to one embodiment of the present disclosure.

FIG. 25 is a drawing for explaining an operating method of a memory device according to one embodiment of the present disclosure.

FIG. 26 is a drawing for explaining an operating method of a memory device according to one embodiment of the present disclosure.

FIG. 27 is a timing diagram for explaining an operating method of a memory device according to one embodiment of the present disclosure.

FIG. 28 is a block diagram exemplarily showing a mobile system to which a memory device according to one embodiment of the present disclosure is applied.

FIG. 29 is a block diagram exemplarily showing an electronic device to which a memory device according to one embodiment of the present disclosure is applied.

FIG. 30 is a block diagram exemplarily showing a computing system to which a memory device according to one embodiment of the present disclosure is applied.

FIG. 31 is a block diagram exemplarily showing a data center to which a memory device according to one embodiment of the present disclosure is applied.

### DETAILED DESCRIPTION OF THE EMBODIMENTS

In the following detailed description, only certain embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Further, expressions written in the singular forms can be comprehended as the singular forms or plural forms unless clear expressions such as “a”, “an”, or “single” are used. Terms including an ordinal number, such as first and second, are used for describing various constituent elements, but the constituent elements are not limited by the terms. These terms are used only to discriminate one constituent element from other constituent elements.

Hereinafter, the present disclosure will be described in more detail through examples. These examples are just for illustrating the present disclosure, and the right protection scope of the present disclosure is not limited by the examples.

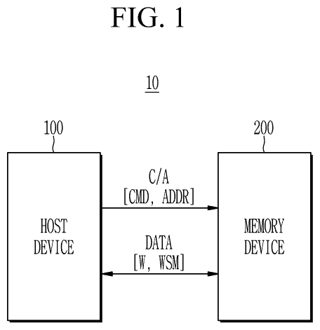

FIG. 1 is a block diagram illustrating a memory system according to one embodiment of the present disclosure.

Referring to FIG. 1, the memory system 10 may include a host device 100 and a memory device 200.

In some embodiments, the host device 100 may be one of various types of processors, such as a central processing unit (CPU) and a graphic processing unit (GPU).

The host device 100 can store data DATA in the memory device 200 or read data DATA from the memory device 200. For example, the host device 100 can control the memory device 200 by transmitting various types of commands and addresses to the memory device 200 through command/address signals C/A.

In some embodiments, the command/address signals C/A may represent command CMD and address ADDR information. For example, the command/address signals C/A can indicate a read command, a write command, or a multi-activate command. The command/address signals C/A can indicate one or more bank addresses, row addresses, or column addresses. However, the embodiment is not necessarily limited thereto, and the command/address signals C/A can represent various types of commands and addresses.

The memory device 200 may include a plurality of memory cells. A plurality of memory cells can be connected to a plurality of word lines, a plurality of bit lines, and a plurality of source lines. For a more concise explanation, below, it is assumed that the memory device 200 is a resistive memory, more specifically, a magnetoresistive random access memory MRAM. However, the embodiment is not necessarily limited thereto, and the memory device 200 may be implemented as various types of memory devices.

The memory device 200 can store a plurality of weight values W received from the host device 100 in a plurality of memory cells in response to a write command from the host device 100.

The memory device 200 can perform a multiply-and-accumulation (MAC) operation based on a plurality of weight values W in response to a multiple activation command (i.e., a multiple-row activation command) from the host device 100. For example, the memory device 200 can receive multiple activation commands and row addresses from the host device 100. In this case, the memory device 200 can, in response to a multiple activation command, compute weighted sums WSM based on weight values W stored in a plurality of memory cells corresponding to row addresses. The specific method by which the memory device 200 calculates weighted sums WSM will be described in more detail with reference to the drawings below.

The memory device 200 can convert the calculated weighted sum into a digital signal based on the weight values W stored in a plurality of memory cells. A specific method by which the memory device 200 converts the weighted sum WSM into a digital signal will also be described in more detail with reference to the drawings below.

The memory device 200 can output weighted sums WSM to the host device 100 in response to a read command from the host device 100. According to an embodiment of the present disclosure, the memory device 200 can output weighted sums WSM calculated based on a plurality of weight values W in response to the control of the host device 100. In this case, the number of times the host device 100 accesses the memory device 200 to compute the weighted sums WSM can be minimized. Accordingly, since the bottleneck caused by the communication speed of the host device 100 and the memory device 200 can be minimized, the operating speed of the memory system 10 can be improved.

In some embodiments, a multi-activate command may be a command that activates multiple word lines of the memory device 200. According to an embodiment of the present disclosure, multiple word lines of the memory device 200 can be activated simultaneously.

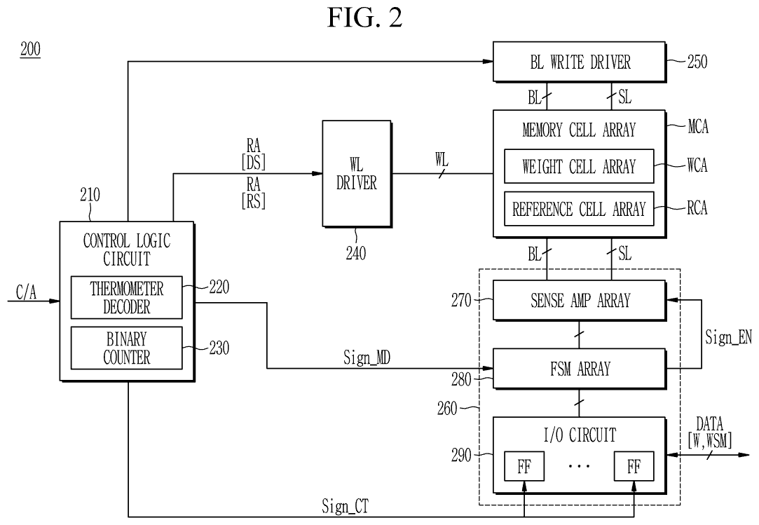

FIG. 2 is a block diagram illustrating a memory device according to one embodiment of the present disclosure.

Referring to FIG. 2, the memory device 200 may include a control logic circuit 210, a word line driver 240, a bit line write driver 250, an analog-to-digital converter (ADC) 260, and a memory cell array MCA. The control logic circuit 210 may include a thermometer decoder 220 and a binary counter 230.

The control logic circuit 210 can receive command/address signals C/A provided from the host device 100 in FIG. 1. The control logic circuit 210 can decode the command/address signals C/A into a command CMD and an address ADDR. In this case, the address ADDR may include a bank address, a row address RA, or a column address.

The control logic circuit 210 can provide a row address RA to the word line driver 240, and the word line driver 240 can activate some of the plurality of word lines WL based on the row address RA. In some embodiments, the control logic circuit 210 may cause the word line driver 240 to activate some of the word lines WL connected to the memory cell array MCA based on a row address RA received along with a multiple activation command.

The control logic circuit 210 can control the bit line write driver 250 based on a write command from the host device 100. The bit line write driver 250 can store data in a plurality of memory cells included in a memory cell array MCA by applying voltages to the bit line BL and the source line SL based on the control of the control logic circuit 210.

In some embodiments, the control logic circuit 210 may provide multiple row addresses RA corresponding to the weighted cell array WCA to the word line driver 240 in response to a multiple enable command. In this case, multiple row addresses RA can correspond to domain signals DS. Domain signals DS can represent weight values W and values to be MAC-operated. For example, weighted sums WSM can be determined through MAC operations of domain signals DS and weight values W. According to the embodiment of the present disclosure, the host device 100 can represent the weight values W and the domain signals DS to be MAC-operated in the form of a row address.

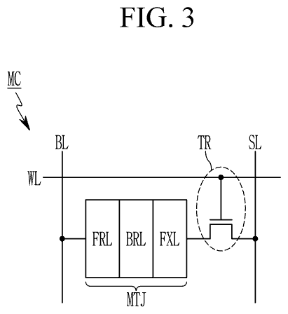

In some embodiments, the control logic circuit 210 may provide a plurality of row addresses RA corresponding to the reference cell array RCA to the word line driver 240 to output a weighted sum value according to the MAC operation of the domain signals DS and the weight values W as a plurality of bits. In this case, multiple row addresses RA can correspond to reference signals RS. The MAC operation for the domain signal DS and weight values W, and the reference signal RS for outputting the weighted sum WSM according to the MAC operation as multiple bits will be described in more detail with reference to FIG. 3 and below.

A memory cell array MCA may include a weight cell array WCA and a reference cell array RCA. Each of the weight cell array WCA and the reference cell array RCA may include a plurality of memory cells arranged in the row direction and the column direction. A plurality of memory cells can be connected to a plurality of word lines WL extending in the row direction, a plurality of bit lines BL extending in the column direction, and a plurality of source lines SL.

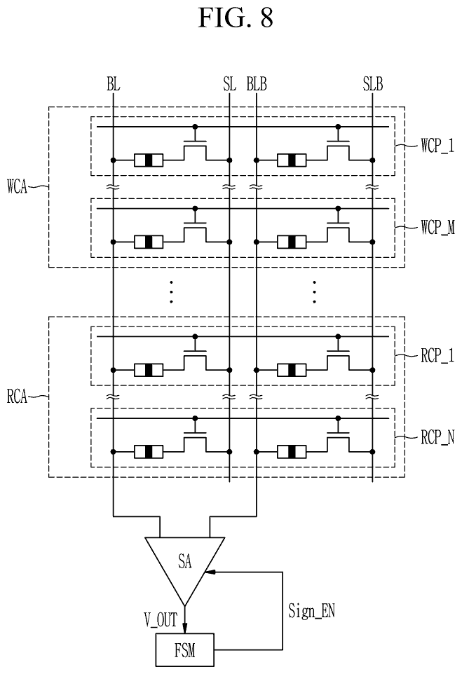

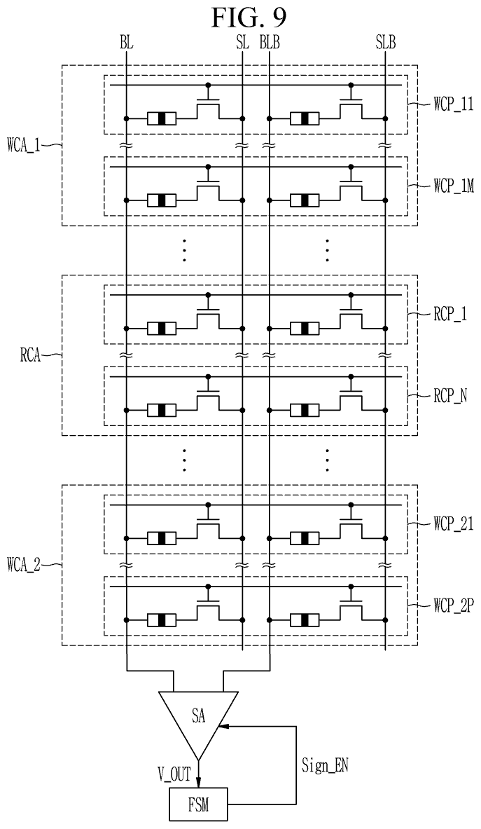

In some embodiments, a plurality of weight cells included in a weight cell array WCA and a plurality of reference cells corresponding thereto included in a reference cell array RCA may be connected to different word lines and may be connected to the same bit line and source line. The weight cells included in the weight cell array WCA and the reference cells included in the reference cell array RCA can be arranged in different rows. The specific implementation method will be described with reference to FIG. 8 and FIG. 9 below.

In some embodiments, weight cells included in a weight cell array WCA may store weight values to be used in MAC operations. In some embodiments, the reference cells included in the reference cell array RCA can store weight values for converting a weighted sum based on the weight values stored in the weight cell array WCA into a digital signal. For convenience of explanation below, the weight values stored in the reference cell array RCA may also be referred to as reference values to distinguish them from the weight values stored in the weight cell array WCA.

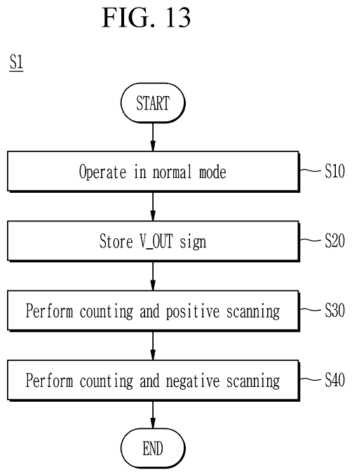

The thermometer decoder 220 can cause the control logic circuit 210 to output a row address RA having a certain rule based on the mode signal Sign_MD. For example, the thermometer decoder 220 may activate M word lines among a plurality of word lines connected to the reference cell array RCA in the N-th time point, and (M+1) word lines in the (N+1)-th time point that follows. The thermometer decoder 220 can perform the above-described operation in synchronization with the counting signal Sign_CT output from the binary counter 230. Specific details will be explained with reference to FIG. 13 and below. For example, the Nth time point and the (N+1)-th time point may be synchronized with counting signal Sign_CT.

A binary counter 230 can count the number of read operations hereinafter also referred to as scanning or reference scanning for a reference cell array RCA and output a counting signal Sign_CT. Specifically, the binary counter 230 can count the number of clocks on which a read operation is performed for the reference cell array RCA to convert a weighted sum based on a domain signal DS and a weight values W stored in a weight cell array WCA into a plurality of bits. A binary counter 230 can provide a counting signal Sign_CT to a flip-flop FF. Specific details will be explained with reference to FIG. 13 and below.

The ADC 260 can convert a weighted sum output as an analog signal from a memory cell array MCA into a digital signal and output the digital signal as data DATA. The ADC 260 may include a sense amplifier array 270, a finite state machine (FSM) array 280, and an input/output circuit 290.

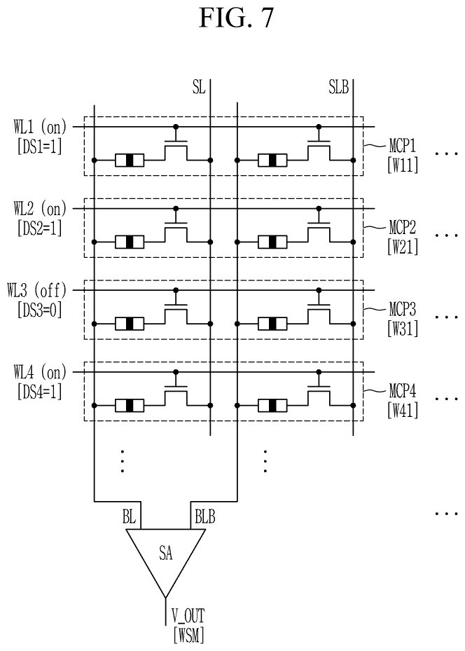

The sense amplifier array 270 may include a plurality of sense amplifiers. The sense amplifier array 270 can be connected to a memory cell array MCA through a plurality of bit lines BL. In some embodiments, the sense amplifier array 270 may output a weighted sum based on the weight values of the weight cells connected to the plurality of activated word lines. Alternatively, in some embodiments, the sense amplifier array 270 may output an output signal based on the calculation of the weighted sum and the reference value stored in the reference cell array RCA. Specific details will be explained with reference to FIG. 7.

The finite state machine array 280 may include a plurality of finite state machines. In some embodiments, the finite state machine array 280 may sense the level of an output signal output from the sense amplifier array 270. The finite state machine array 280 can provide the sign of the weighted sum as a sign signal to the flip-flop FF. The finite state machine array 280 can output an enable signal Sign_EN to the sense amplifier array 270 that controls the operation of the sense amplifier array 270 based on the level of the mode signal Sign_MD provided from the thermometer decoder 220, the weighted sum sign signal, and the output signal output from the sense amplifier array 270. Specific details will be explained with reference to FIG. 13.

The input/output circuit 290 can receive data DATA from the host device 100 or transmit data DATA to the host device 100. For example, the input/output circuit 290 can provide weight values W received from the host device 100 to the bit line write driver 250 to write them into the memory cell array MCA, or can express the generated weighted sum WSM as a plurality of bits and output them to the host device 100.

The input/output circuit 290 may include a plurality of flip-flops FF. The plurality of flip-flops FF can store a weighted sum calculated based on weight values stored in a weight cell array WCA in the form of a plurality of bits based on a counting signal Sign_CT provided from a binary counter 230. The input/output circuit 290 can output a weighted sum WSM of multiple bits stored in a flip-flop FF as data DATA to the host device 100.

FIG. 3 is a drawing for explaining a memory cell according to one embodiment of the present disclosure.

Referring to FIG. 3, a memory cell MC may include a variable resistance element MTJ and a transistor TR. The variable resistance element MTJ can be implemented as a magnetic tunnel junction. Hereinafter, the variable resistance element MTJ and the magnetic tunnel junction may be referred to as the same.

One end of the variable resistance element MTJ can be connected to a bit line BL, and the other end can be connected to a transistor TR. One end of the transistor TR can be connected to a variable resistance element MTJ, the other end can be connected to a source line SL, and the gate of the transistor TR can be connected to a word line WL and operate in response to the voltage of the word line WL. In some embodiments, the memory device 200 of FIG. 1 can write data into a memory cell MC by adjusting the resistance value of the memory cell MC.

The variable resistance element MTJ may include a free layer FRL, a barrier layer BRL, and a fixed layer FXL. The barrier layer BRL can be located between the free layer FRL and the fixed layer FXL. The free layer FRL can be connected to a bit line BL, and the fixed layer FXL can be connected to a transistor TR. The magnetization direction of the fixed layer FXL can be fixed in a specific direction, and the magnetization direction of the free layer FRL can be changed depending on specific conditions e.g., the direction of the write current. In some embodiments, the variable resistance element MTJ may further include an anti-ferromagnetic layer for fixing the magnetization direction of the fixed layer FXL.

In some embodiments, the free layer FRL may comprise a material having a changeable magnetization direction. The magnetization direction of the free layer FRL can be changed by electrical or magnetic factors provided from outside or inside the memory cell. The free layer FRL may include a ferromagnetic material including at least one of cobalt Co, iron Fe, and nickel Ni. For example, the free layer FRL can include at least one selected from FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO and Y₃Fe₅O₁₂. However, the examples are not necessarily limited thereto.

In some embodiments, the thickness of the barrier layer BRL may be thinner than the spin diffusion distance. The barrier layer BRL may contain a non-magnetic material. As an example, the barrier layer BRL may include at least one selected from oxides of magnesium Mg, titanium Ti, aluminum Al, magnesium-zinc MgZn, and magnesium-boron MgB, and nitrides of titanium Ti and vanadium V. However, the examples are not necessarily limited thereto.

In some embodiments, the pinned layer FXL may have a magnetization direction fixed by the antiferromagnetic layer. The fixed layer FXL may include a ferromagnetic material. For example, the fixed layer FXL can include at least one selected from CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO and Y₃Fe₅O₁₂. In some embodiments, the antiferromagnetic layer may include an anti-ferromagnetic material. For example, the antiferromagnetic layer can include at least one selected from PtMn, IrMn, MnO, MnS, MnTe, MnF₂, FeCl₂, FeO, CoCI₂, CoO, NiCl₂, NiO and Cr. However, the examples are not necessarily limited thereto.

Depending on the direction of the current flowing through the variable resistance element MTJ, the magnetization direction of the free layer FRL can change. Current can be generated by controlling the voltages of the bit line BL and the source line SL when the transistor TR is turned on by the voltage of the word line WL.

For example, when current flows from the bit line BL to the source line SL, the magnetization direction of the free layer FRL can become the same as the magnetization direction of the fixed layer FXL, and this state can be referred to as a parallel state Parallel; P. Conversely, when current flows from the source line SL to the bit line BL, the magnetization direction of the free layer FRL can be opposite to the magnetization direction of the pinned layer FXL, and this state can be referred to as an anti-parallel state AP.

The resistance of a variable resistance element MTJ can have different resistance values in the parallel state P and the anti-parallel state AP. For example, data can be stored in the memory cell MC according to the resistance value of the variable resistance element MTJ, and by reading the resistance value of the variable resistance element MTJ, data e.g., bit “1” or bit “0” stored in the memory cell MC can be read out.

For convenience of explanation, in the following, if a memory cell MC is a memory cell included in a weighted cell array WCA of FIG. 2, the memory cell MC may be referred to as a weighted cell. Similarly, if a memory cell MC is a memory cell included in a reference cell array RCA of FIG. 2, the memory cell MC may be referred to as a reference cell. The MRAM cell's conductance can be interpreted analogously to represent a weight in CIM architectures. This enables MAC operations, similar to RRAM or PCM-based CIM arrays.

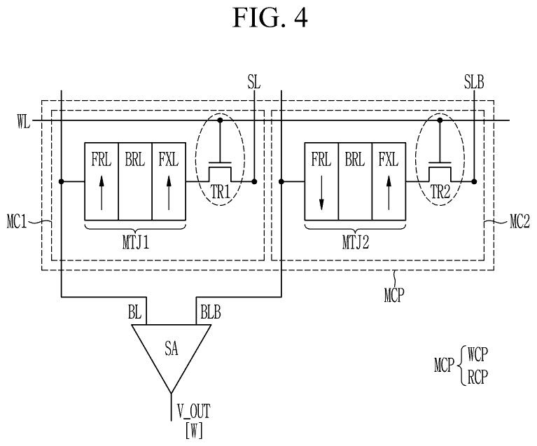

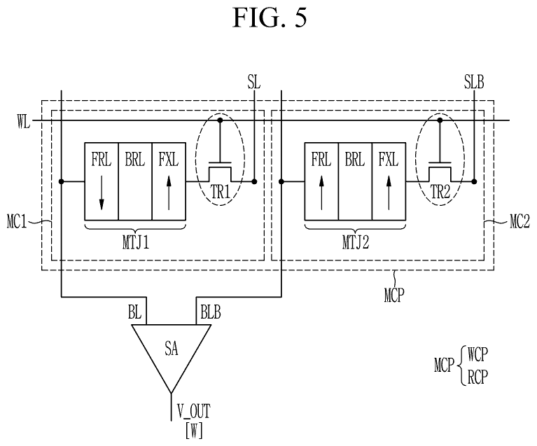

FIGS. 4 and 5 are drawings for explaining a memory cell pair according to one embodiment of the present disclosure.

Referring to FIGS. 4 and 5, a memory cell pair MCP may include a first memory cell MC1 and a second memory cell MC2. The first memory cell MC1 may include a first variable resistance element MTJ1 and a first transistor TR1, and the second memory cell MC2 may include a second variable resistance element MTJ2 and a second transistor TR2.

One end of the first variable resistor element MTJ1 can be connected to a bit line BL, and the other end can be connected to a first transistor TR1. One end of the first transistor TR1 can be connected to the first variable resistor element MTJ1, and the other end can be connected to the source line SL.

One end of the second variable resistor element MTJ2 can be connected to the bit line BLB, and the other end can be connected to the second transistor TR2. One end of the second transistor TR2 can be connected to the second variable resistor element MTJ2, and the other end can be connected to the source line SLB. Hereinafter, for convenience of explanation from the perspective of a memory cell pair MCP, the bit line BLB and the source line SLB connected to the second memory cell MC2 may be referred to as a complementary bit line BLB and a complementary source line SLB, respectively.

The gate of the first transistor TR1 and the gate of the second transistor TR2 can be connected to the same word line WL. For example, the first memory cell MC1 and the second memory cell MC2 are connected to the same word line WL and can be arranged in the row direction.

A bit line BL connected to the first memory cell MC1 and a complementary bit line BLB connected to the second memory cell MC2 can be connected to a sense amplifier SA. The sense amplifier SA can amplify the values of data stored in the first memory cell MC1 and the second memory cell MC2 and output them as an output signal V_OUT.

A first memory cell MC1 and a second memory cell MC2 included in a memory cell pair MCP can have different states.

For example, referring to FIG. 4, the first memory cell MC1 may be in a parallel state P in which the magnetization directions of the free layer FRL and the fixed layer FXL are the same, and the second memory cell MC2 may be in an anti-parallel state AP in which the magnetization directions of the free layer FRL and the fixed layer FXL are opposite.

On the other hand, referring to FIG. 5, the first memory cell MC1 may be in an anti-parallel state AP in which the magnetization directions of the free layer FRL and the fixed layer FXL are opposite, and the second memory cell MC2 may be in a parallel state P in which the magnetization directions of the free layer FRL and the fixed layer FXL are the same.

A memory cell pair MCP according to one embodiment of the present disclosure can store weight values based on a first memory cell MC1 and a second memory cell MC2 storing complementary states with each other.

For example, as illustrated in FIG. 4, when the first memory cell MC1 is in a parallel state P and the second memory cell MC2 is in an anti-parallel state AP, the corresponding memory cell pair MCP can be defined as having a weight value of ‘1’.

Conversely, as illustrated in FIG. 5, when the first memory cell MC1 is in an anti-parallel state AP and the second memory cell MC2 is in a parallel state P, the corresponding memory cell pair MCP can be defined as having a weight value of ‘−1’.

For convenience of explanation, in the following, when the first memory cell MC1 and the second memory cell MC2 are memory cells included in a weighted cell array WCA of FIG. 2, a memory cell pair MCP including the first memory cell MC1 and the second memory cell MC2 may be referred to as a weighted cell pair WCP. Similarly, when the first memory cell MC1 and the second memory cell MC2 are memory cells included in the reference cell array RCA of FIG. 2, the memory cell pair MCP including the first memory cell MC1 and the second memory cell MC2 may be referred to as a reference cell pair RCP.

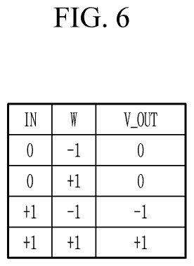

FIG. 6 is a drawing for explaining an output signal based on a weight value and an input signal according to a state of a memory cell pair according to one embodiment of the present disclosure. For example, the sense amplifier SA connected the memory cell pair may output ternary outputs such as −1, 0, and 1 in response to a binary input such as 0 and 1. The output of the sense amplifier SA may reflect the polarity and presence of accumulated current from the bit line BL and the complementary bit line BLB. In an embodiment, the sese amplifier SA may be implemented using ternary comparators, two-reference-level ADC, or thresholding logic.

Referring to FIGS. 4 to 6, an input signal IN may mean a signal applied to a word line WL, a weight values W may mean a weight stored in a memory cell pair MCP, and an output signal V_OUT may mean an output signal from the sense amplifier SA.

When the word line WL is not activated, the input signal IN can be ‘0’, and accordingly, the arithmetic value can be ‘0’ regardless of the value of the weight values W stored in the memory cell pair MCP, and in response, the sense amplifier SA can output an output signal V_OUT of low level or logic ‘O’.

On the other hand, when the word line WL is activated, the input signal IN can be ‘1’, and accordingly, when the weight values W is ‘−1’ i.e., the example of FIG. 5, the arithmetic value can be ‘−1’, and correspondingly, the sense amplifier SA can output an output signal V_OUT of low level or logic ‘O’.

In addition, when the word line WL is activated, the input signal IN can be ‘1’, and accordingly, when the weight values W is ‘1’ i.e., the example of FIG. 4, the arithmetic value can be ‘1’, and correspondingly, the sense amplifier SA can output an output signal V_OUT of a high level or logic ‘1’. In an embodiment, the values of ‘−1 or “+1” may be a logical or symbolic value, not a literal voltage.

In FIGS. 4 and 5, only a single memory cell pair MCP storing one weight values W is illustrated, so that the output of the sense amplifier SA corresponds to the weight values W of the corresponding memory cell pair MCP, but the embodiment is not limited thereto. Below, we describe a method for generating a weighted sum WSM according to a plurality of weight values W stored in multiple memory cell pairs MCP arranged in the same column direction and an input signal.

FIG. 7 is a drawing for explaining the computation of a memory device according to one embodiment of the present disclosure.

Referring to FIG. 7, a plurality of memory cell pairs MCP1 to MCP4 can be connected to a plurality of word lines WL1 to WL4. For a more concise explanation, FIG. 7 illustrates a representative example of a plurality of memory cell pairs MCP1 to MCP4 connected to the first to fourth word lines WL1 to WL4, but the embodiment is not limited thereto. The scope of the present disclosure is not limited to the number of word lines and the number of memory cell pairs.

A first memory cell pair MCP1 may include a plurality of memory cells connected to a first word line WL1. The second memory cell pair MCP2 may include a plurality of memory cells connected to the second word line WL2. A third memory cell pair MCP3 may include a plurality of memory cells connected to a third word line WL3. The fourth memory cell pair MCP4 may include a plurality of memory cells connected to the fourth word line WL4.

The first to fourth memory cell pairs MCP1 to MCP4 can be connected to the same bit line BL, complementary bit line BLB, source line SL, and complementary source line SLB. For example, the first to fourth memory cell pairs MCP1 to MCP4 can be arranged along the direction in which the bit lines extend or in the column direction.

As described with reference to FIGS. 4 to 6, each of the first to fourth memory cell pairs MCP1 to MCP4 can store weight values based on the fact that a plurality of memory cells included in each store different states. For example, a first memory cell pair MCP1 can store a first weight values W11, a second memory cell pair MCP2 can store a second weight values W21, a third memory cell pair MCP3 can store a third weight values W31, and a fourth memory cell pair MCP4 can store a fourth weight values W41. The first to fourth weight values W11 to W41 can each have a value of ‘1’ or ‘−1’ as described above.

The host device 100 in FIG. 1 can control the memory device 200 in FIG. 1 to perform a MAC operation by transmitting a multiple activation command. For example, the host device 100 can provide a multiple activation command and multiple row addresses RA to the memory device 200.

The memory device 200 can activate some of the word lines in response to multiple row addresses provided with a multiple activation command. For example, the word line driver 240 in FIG. 2 can activate word lines corresponding to multiple received row addresses RA.

For example, when row addresses corresponding to the first word line WL1, the second word line WL2, and the fourth word line WL4 are received, the word line driver 240 can activate the first word line WL1, the second word line WL2, and the fourth word line WL4. On the other hand, if a row address corresponding to the third word line WL3 is not included among the row addresses received with the multiple activation command, the word line driver 240 may not activate the third word line WL3.

In some embodiments, the host device 100 may determine the domain signals DS of FIG. 1 to be MAC-operated based on the row addresses to be provided along with the multiple activation command. For example, the host device 100 can determine the first domain signal DS1 as ‘1’ by providing a row address for the first word line WL1 to the memory device 200 along with a multiple activation command. Similarly, the host device 100 can determine the second domain signal DS2 and the fourth domain signal DS4 to be ‘1’ by providing row addresses for the second word line WL2 and the fourth word line WL4 to the memory device 200 along with a multiple activation command. On the other hand, the host device 100 can determine the third domain signal DS3 as ‘0’ by providing a row address for the third word line WL3 to the memory device 200 along with a multiple activation command.

The sense amplifier SA can be connected to a bit line BL and a complementary bit line BLB. The sense amplifier SA can output a weighted sum WSM calculated based on weight values stored in a plurality of memory cell pairs MCP1 to MCP4 connected to corresponding bit lines BL and complementary bit lines BLB as an output signal V_OUT.

Specifically, the size of the weighted sum WSM can be determined as shown in the mathematical expression 1 below.

$${WSM}_{1} = \sum DSk \times {W}_{k 1} \qquad Equation 1$$

Here, WSM₁ may represent a weighted sum based on the first to fourth memory cell pairs MCP1 to MCP4 arranged in the first column as illustrated in FIG. 7 and the first to fourth domain signals DS1 to DS4, DSₖ may represent a value of the k-th domain signal, and WK1 may represent a weight stored in each of the first to fourth memory cell pairs MCP1 to MCP4 in the first column. In the embodiment illustrated in FIG. 7, k can have a value greater than or equal to 1 and less than or equal to 4.

Depending on the sign of the arithmetic value of the weighted sum WSM according to the mathematical formula described above, the sense amplifier SA can output a low-level output signal V_OUT or a high-level output signal V_OUT. Specifically, the sense amplifier SA can output a high-level output signal V_OUT when the sign of the weighted sum WSM is positive, and can output a low-level output signal V_OUT when the sign of the weighted sum WSM is negative or ‘0’.

FIGS. 8 and 9 are drawings for explaining a memory cell array according to one embodiment of the present disclosure.

Referring to FIG. 8, the memory cell array MCA may include a weighted cell array WCA and a reference cell array RCA. A weighted cell array WCA may include first to M-th weighted cell pairs WCP_1 to WCP_M. A reference cell array RCA may include first to N-th reference cell pairs RCP_1 to RCP_N.

The first to M-th weight cell pairs WCP_1 to WCP_M and the first to N-th reference cell pairs RCP_1 to RCP_N can be connected to the same bit line BL and complementary bit line BLB or source line SL and complementary source line SLB. The sense amplifier SA can output, as an output signal V_OUT, a weighted sum calculated based on the weight values stored in the first to M-th weight cell pairs WCP_1 to WCP_M and the domain signal. The sense amplifier SA can output a value whose weighted sum is changed as an output signal V_OUT depending on whether the first to N-th reference cell pairs RCP_1 to RCP_N are activated.

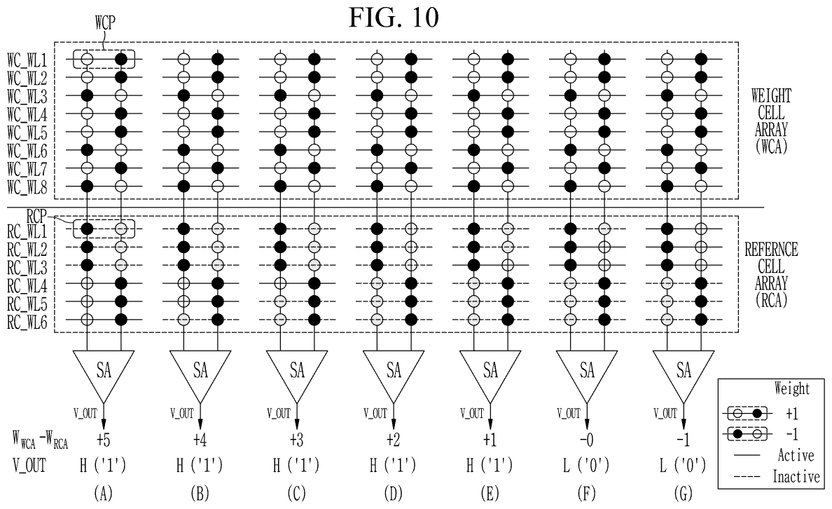

The finite state machine FSM can receive an output signal V_OUT from the sense amplifier SA. A finite state machine FSM can output an enable signal Sign_EN based on the output signal V_OUT. Specifically, the finite state machine FSM can output an enable signal Sign_EN that stops the operation of the sense amplifier SA in response to an inversion in the level of the output signal V_OUT. Specific details will be explained with reference to FIG. 10 and below.

FIG. 9 is a drawing for explaining a memory cell array according to one embodiment of the present disclosure. Below, the structural differences from the embodiment illustrated in FIG. 8 are explained.

Referring to FIG. 9, the memory cell array MCA may include a first weighted cell array WCA_1, a second weighted cell array WCA_2, and a reference cell array RCA. The first weight cell array WCA_1 may include first to M-th weight cell pairs WCP_11 to WCP_1M. The second weight cell array WCA_2 may include first to P-th weight cell pairs WCP_21 to WCP_2P. A reference cell array RCA may include first to N-th reference cell pairs RCP_1 to RCP_N.

In some embodiments, the reference cell array RCA may be arranged on one side of the bit line of the weight cell array WCA along the direction in which the bit line BL extends, as illustrated in FIG. 8. In some other embodiments, the reference cell array RCA may be placed between the weight cell arrays WCA as illustrated in FIG. 9. However, the embodiment is not necessarily limited thereto, and the arrangement relationship of the weight cell array WCA and the reference cell array RCA may be implemented in various ways depending on the embodiment.

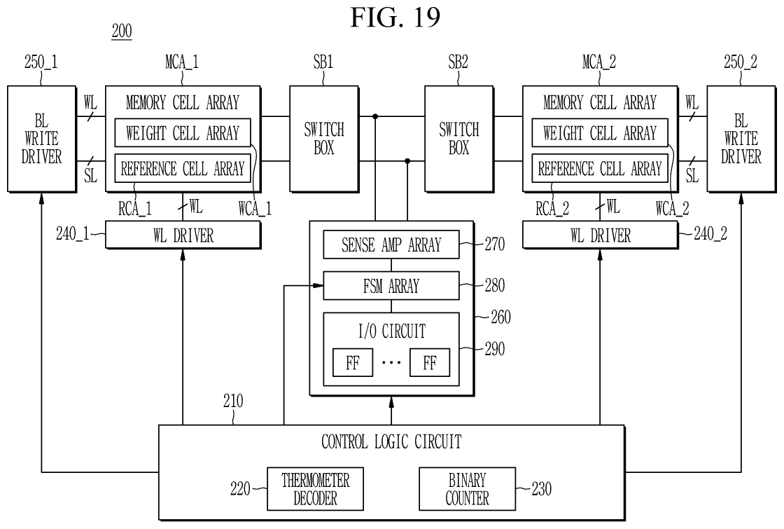

In addition, for convenience of explanation, the memory device 200 will be described below as an embodiment having a folded bit line structure, and the embodiments illustrated in FIGS. 19 to 27 will be described as an embodiment having an open bit line structure.

FIG. 10 is a drawing for explaining the computation of a memory device according to one embodiment of the present disclosure. For convenience of explanation below, it is assumed that the weighted cell array WCA includes eight weighted cell pairs WCP and the reference cell array RCA includes six reference cell pairs RCP (e.g., three reference cell pairs for positive scanning, which will be described below, and the other three reference cell pairs for negative scanning, which will be described below).

Also, for convenience of explanation, when all word lines connected to the weight cell array WCA are activated and all word lines connected to the reference cell array RCA are deactivated, the arithmetic value calculated according to the weight values stored in the weight cell pair WCP is defined as a weighted sum W_{WCA}.

Also, for convenience of explanation, when some word lines in a reference cell array RCA are activated, the arithmetic value calculated based on the weight values stored in multiple reference cell pairs RCP to which the activated word lines are connected is defined as a reference sum W_{RCA}.

Referring to FIG. 10, in all cases (A) to (G), the first to eighth weight cell word lines WC_WL1 to WC_WL8 can be activated. For example, the first to eighth domain signals can have the value ‘1’.

A method of operating a memory device according to one embodiment of the present disclosure may sequentially activate or deactivate a plurality of reference cell word lines included in a reference cell array RCA to convert a sum of weight values stored in a plurality of weight cell pairs connected to activated word lines, i.e., a MAC operation value i.e., a weighted sum of a domain signal and weight values, into a plurality of bits.

As described above, since the first to eighth weight cell word lines WC_WL1 to WC_WL8 are activated in all of (A) to (G), the arithmetic value of the weighted sum W_{WCA} of the weight cell array WCA can have a value of ‘2’. For example, a memory cell pair having a sequence of an open circle followed by a closed circle stores a weight value of “+1” as described with reference to FIG. 4 whereas a memory cell pair with the opposite sequence stores a weight value of “−1” as described with reference to FIG. 5. In the illustrated example, eight memory cell pairs connected to the first to eighth weight cell word lines WC_WL1 to WC_WL8 are associated with the sense amplifier SA, of which five pairs store “+1” (e.g., the first, second, fourth, fifth, and seventh pairs of the first, second, fourth, fifth, and seventh weight cell word lines WC_WL1, WC_WL2, WC_WL4, WC_WL5, and WC_WL7), and three pairs store “−1” (e.g., the third, sixth, and eighth pairs of the third, sixth, and eighth weight cell word lines WC_WL3, WC_WL6, and WC_WL8). When all eight word lines WC_WL1 to WC_WL8 are activated, the cumulative value is 2. The lines intersecting the open and closed circles may indicate that the corresponding word lines are in an active state, while dotted lines represent inactive word lines. For example, in the weight cell array WCA, all memory cell pairs are associated with solid lines, indicating that weight cell word lines WC_WL1 to WC_WL8 are activated. In case (A), reference cell word lines RC_WL1 to RC_WL3 are shown as dotted lines, indicating an inactive state, whereas reference cell word lines RC_WL4 to RC_WL6 are shown as solid lines, indicating that they are active.

Meanwhile, in (A), since the 4th to 6th reference cell word lines RC_WL4 to RC_WL6 are activated, the reference matching W_{RCA} can be ‘3’. Accordingly, the arithmetic value W_{WCA}-W_{RCA} of the output signal V_OUT output from the sense amplifier SA can be ‘5’, and correspondingly, the sense amplifier SA can output an output signal V_OUT of a high level or logic ‘1’.

In addition, in (B) and (C), since the word lines connected to the reference cell pair RCP that stores the reference value of ‘1’ are sequentially reduced by one compared to A, the arithmetic value W_{WCA}-W_{RCA} of the output signal V_OUT output from the sense amplifier SA in (B) can be ‘4’, and the arithmetic value W_{WCA}-W_{RCA} of the output signal V_OUT output from the sense amplifier SA in (C) can be ‘3’, and the sense amplifier SA can output a high-level output signal V_OUT.

On the other hand, in (E), only the third reference cell word line RC_WL3 is activated, so the reference sum W_{RCA} can be ‘−1’. Accordingly, the arithmetic value W_{WCA}-W_{RCA} of the output signal V_OUT output from the sense amplifier SA can be ‘1’, and correspondingly, the sense amplifier SA can output a high-level output signal V_OUT.

Meanwhile, in (F) and (G), since the word lines connected to the reference cell pair RCP that stores the reference value of ‘−1’ sequentially increase by one compared to E, the arithmetic value W_{WCA}-W_{RCA} of the output signal V_OUT output from the sense amplifier SA in (F) can be ‘−0’, and the arithmetic value W_{WCA}-W_{RCA} of the output signal V_OUT output from the sense amplifier SA in (G) can be ‘−1’, and the sense amplifier SA can invert the level of the output signal V_OUT to output a low-level output signal V_OUT.

A method of operating a memory device according to one embodiment of the present disclosure can count the number of read operations performed on a reference cell array RCA until a signal level of an output signal V_OUT output from the sense amplifier SA is inverted, and convert a weighted sum of a corresponding weighted cell array WCA into a plurality of bits.

The memory device 200 of FIG. 1 according to one embodiment of the present disclosure can compute a weighted sum in response to a multiple activation command received from the host device 100 of FIG. 1. Accordingly, data movement between the host device 100 and the memory device 120 can be minimized, so the operating speed of the memory system 10 in FIG. 1 can be improved.

In addition, according to one embodiment of the present disclosure, since a portion of a memory cell array can be utilized for generating a reference value without using a plurality of comparators or a plurality of capacitor arrays required in a conventional ADC, the area of the memory device 200 can be reduced.

Conventional ADCs require a trim circuit to compensate for the reference voltage size due to PVT variation. On the other hand, since the memory device 200 according to one embodiment of the present disclosure utilizes the same MRAM cell and thereby automatically corrects the reference even for temperature changes, the above-described trim circuit or other circuit may not be required.

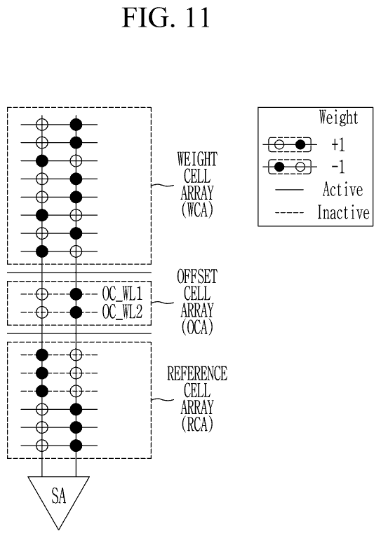

FIG. 11 is a drawing for explaining a memory cell array according to one embodiment of the present disclosure.

Referring to FIG. 11, the memory cell array MCA may include an offset cell array OCA in addition to a weighted cell array WCA and a reference cell array RCA. The offset cell array OCA can be connected to the same bit lines and complementary bit lines or source lines and complementary source lines as the weighted cell array WCA and the reference cell array RCA.

An offset cell array OCA may include offset cell pairs that store predetermined offset weights. In the embodiment illustrated in FIG. 11, the offset cell array OCA may include an offset cell pair connected to a first offset cell word line OC_WL1 and storing a weight of ‘1’, and an offset cell pair connected to a second offset cell word line OC_WL2 and storing a weight of ‘1’. The offset cell array OCA of the embodiment illustrated in FIG. 11 can offset the arithmetic value of the signal output from the sense amplifier SA by ‘2’. Meanwhile, the embodiment is not necessarily limited thereto, and the number of offset cell pairs included in the offset cell array OCA and the weight stored by each offset cell pair may be implemented in various ways depending on the embodiment.

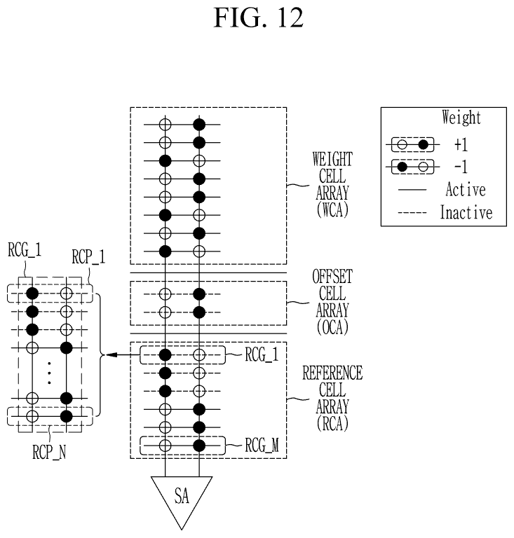

FIG. 12 is a drawing for explaining a memory cell array according to one embodiment of the present disclosure.

Referring to FIG. 12, the reference cell array RCA may include first to M-th reference cell groups RCG_1 to RCG_M. Each of the first to M-th reference cell groups RCG_1 to RCG_M can include the first to N-th reference cell pairs RCP_1 to RCP_N.

In the embodiment illustrated in FIG. 10, during a read operation for the reference cell array RCA, one more reference cell word line is sequentially activated or deactivated, whereas in the embodiment illustrated in FIG. 12, during a read operation for the reference cell array RCA, one more reference cell group can be sequentially activated or deactivated. For example, when the first reference cell group RCG_1 is activated, all reference cell word lines connected to each of the first to N-th reference cell pairs RCP_1 to RCP_N included in the first reference cell group RCG_1 can be activated.

The status of the first to N-th reference cell pairs RCP_1 to RCP_N included in each of the first to M-th reference cell groups RCG_1 to RCG_M can be changed. For example, in a first time interval, the first to N-th reference cell pairs RCP_1 to RCP_N included in a first reference cell group RCG_1 may be stored in a first state such that the reference match has a first value, and in a second time interval, they may be stored in a second state such that the reference match has a second value different from the first value.

As described above, by changing the number of reference cell word lines activated during a read operation for the reference cell array RCA, or by storing various reference values by changing the states of multiple reference cell pairs included in the same reference cell group, the conversion gain of the output signal output from the sense amplifier SA can be implemented in various ways.

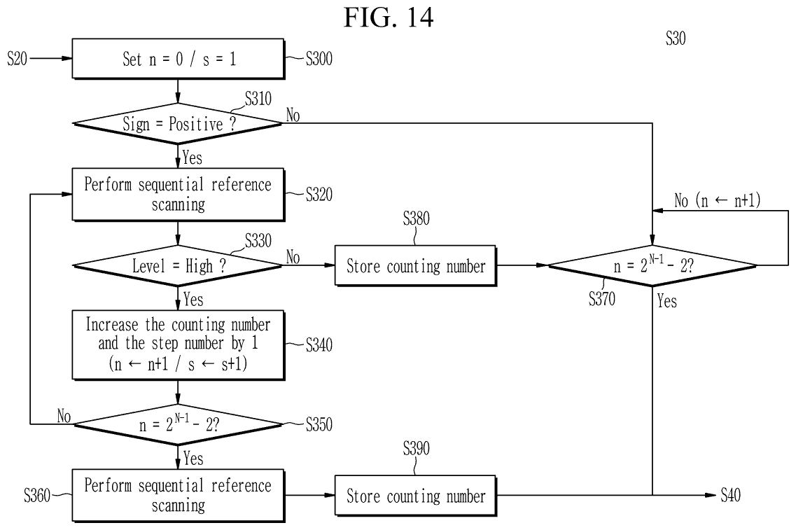

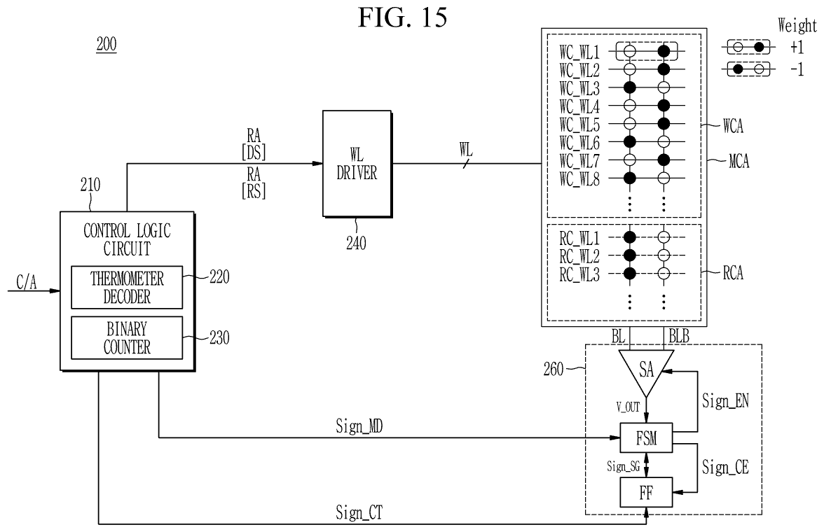

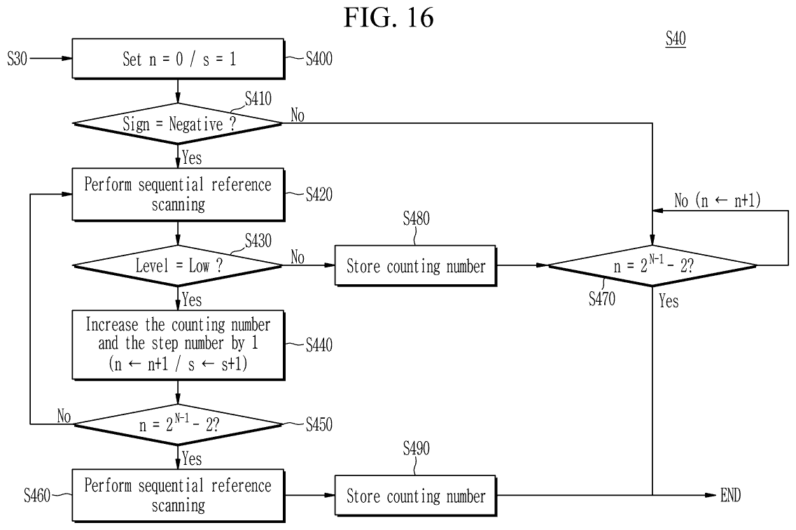

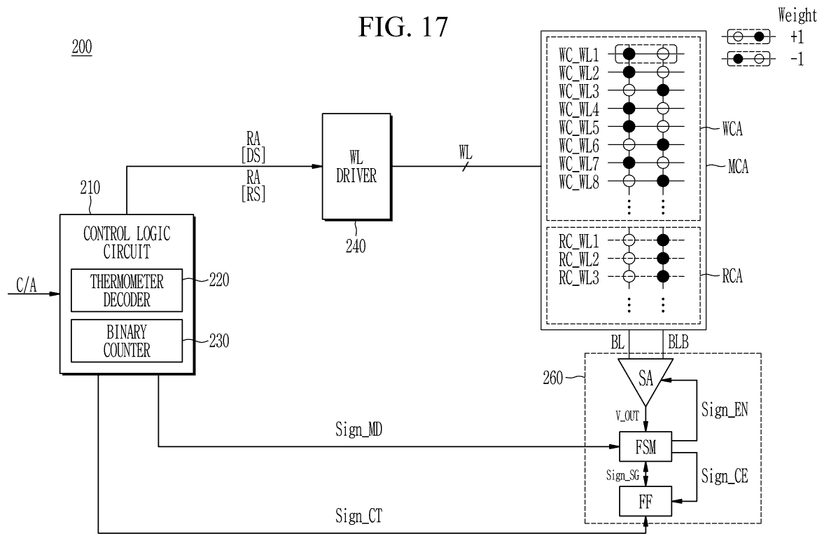

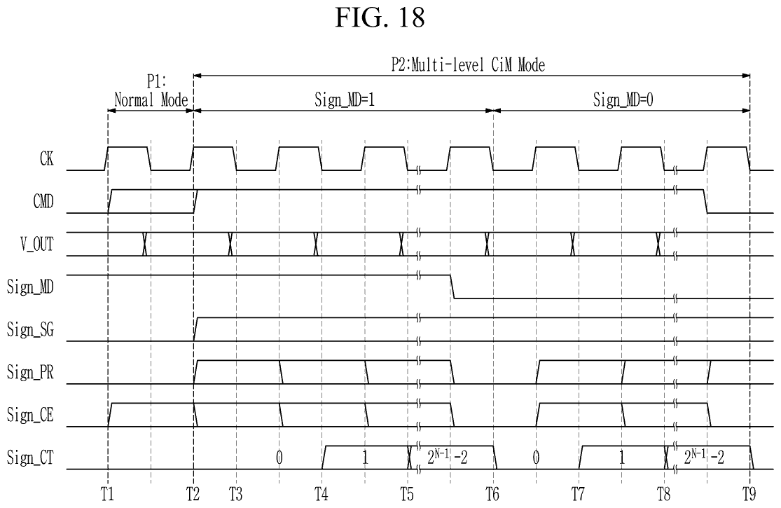

FIG. 13, FIG. 14, and FIG. 16 are flowcharts for explaining an operating method of a memory device according to one embodiment of the present disclosure. FIG. 15 and FIG. 17 are drawings for explaining an operating method of a memory device according to one embodiment of the present disclosure. FIG. 18 is a timing diagram for explaining an operating method of a memory device according to one embodiment of the present disclosure.

Referring to FIGS. 13 to 18, the operating method S1 of the memory device may include step S10 of operating in a normal mode. Specifically, in response to the command CMD transitioning at the first time point T1, the memory device 200 can operate in a normal mode.

The step S10 of operating in the normal mode may include, for example, storing data DATA of FIG. 1, e.g., weight values W provided from the host 100 of FIG. 1 in each of the weight cell array WCA and the reference cell array RCA.

The step S10 of operating in the normal mode may further include a step of calculating a weighted sum based on a plurality of weight values stored in the weight cell array WCA and a domain signal DS of FIG. 2 and outputting the result as an output signal. For example, as illustrated in (D) of FIG. 10, the step S10 for operating in the normal mode may include a step of calculating a weighted sum of weight cell pairs connected to activated weight cell word lines and outputting the result through a sense amplifier while all word lines connected to the reference cell array are deactivated.

The operating method S1 of the memory device may include step S20 of storing a sign of an output signal. Specifically, the step S20 of storing the sign of the output signal may mean storing the sign of the output signal output through the sense amplifier by calculating the weighted sum of the weight cell pairs connected to the activated weight cell word lines while all word lines connected to the reference cell array are inactive, as illustrated in (D) of FIG. 10. In part (B) of FIG. 10, step S20, which involves storing the sign of the output signal, may include storing the sign of the signal generated from the sense amplifier. This output is obtained by calculating the weighted sum of the weight cell pairs connected to the activated weight cell word lines, while reference cell word lines RC_WL4 and RC_WL5—associated with the reference cell array RCA—are active, and all other reference cell word lines remain inactive.

For example, referring to (D) of FIG. 10, since the arithmetic value of the weighted sum is ‘2’, the sense amplifier SA can output a high-level output signal, and the finite state machine FSM can store a sign signal Sign_SG indicating that the sign of the weighted sum is positive in the flip-flop FF in response to the level of the output signal output corresponding to the weighted sum corresponding to the high level.

Specifically, the finite state machine FSM can provide a high-level sign signal Sign_SG indicating that the sign of the weighted sum is positive, or a low-level sign signal Sign_SG indicating that the sign of the weighted sum is negative, to the flip-flop FF in the finite state machine FSM.

The flip-flop FF can store the provided sign signal Sign_SG as the most significant bit MSB. For example, the flip-flop FF can store data of ‘1’ as MSB when the sign of the weighted sum is positive, and can store data of ‘0’ as MSB when the sign of the weighted sum is negative. In this case, the flip-flop FF can store the absolute value of the weighted sum as multiple unsigned bits.

In some embodiments, the flip-flop FF can invert the provided sign signal Sign_SG and store it as the MSB. For example, the flip-flop FF can store data of ‘0’ as MSB when the sign of the weighted sum is positive, and can store data of ‘1’ as MSB when the sign of the weighted sum is negative. In this case, the flip-flop FF can store the weighted sum as multiple bits in two's complement form.

The method of operating the memory device S1 may further include step S30 of performing counting and positive scanning. The operating method S1 of the memory device may further include step S40 of performing counting and negative scanning. Specifically, in response to the command CMD transitioning at the second time point T2, the operating method S1 of the memory device can proceed to step S30 if the sign of the weighted sum of the weight cell array WCA stored through step S10 and step S20 is positive, and can proceed to step S40 if the sign is negative.

For example, the weighted sum of the weighted cell array WCA illustrated in FIG. 15 may be ‘2’, and the weighted sum of the weighted cell array WCA illustrated in FIG. 17 may be ‘−2’. For example, in FIG. 15, among memory cells connected to the sense amplifier SA, a number of the memory cell pair having an open circle/a closed circle (weight value of “+1”) is 5, and a number of the memory cell pairs having a closed circle/an open circle (weight value of “−1) is 3. The weight sum of the sense amplifier is 2. For example, in FIG. 17, among memory cells connected to the sense amplifier SA, a number of the memory cell pair having an open circle and a closed circle in this order (weight value of “+1”) is 3, and a number of the memory cell pairs having a closed circle and an open circle in this order (weight value of “−1) is 5. The weight sum of the sense amplifier is −2. Accordingly, since the sign of the weighted sum of the weighted cell array WCA illustrated in FIG. 15 corresponds to a positive number, the step S30 of converting the weighted sum into multiple bits can be performed, and since the sign of the weighted sum of the weighted cell array WCA illustrated in FIG. 17 corresponds to a negative number, the step S40 of converting the weighted sum into multiple bits can be performed.

Here, performing positive scanning may mean performing scanning over a weight cell array WCA whose sign of the weighted sum is positive, and performing negative scanning may mean performing scanning over a weight cell array WCA whose sign of the weighted sum is negative. In the normal mode between T1 and T2, the sign of the weighted sum of the weight cell array WCA is determined, and the multi-level CIM mode between T2 and T9, the weighted sum of the weighted cell array WCA may be decoded using the reference cell array RCA by the positive scanning or negative scanning depending on the determined sign of the weight sum of the weight cell array WCA.

In positive scanning, the thermometer decoder 220 can output a high level mode signal Sign_MD to the finite state machine array 280, and in negative scanning, the thermometer decoder 220 can output a low level mode signal Sign_MD to the finite state machine array 280. The thermometer decoder 220 can control the reference cell word line RC_WL that is activated based on the mode signal Sign_MD.

For example, to perform positive scanning with positive weight values, the reference cell word line connected to the reference cell pair having a negative reference value must be activated, and the thermometer decoder 220 can control the word line driver 240 to activate the reference cell word line connected to the reference cell pair having a negative reference value. For example, during positive scanning, each read operation performed on the weight cell array WCA and the reference cell array RCA may decrease the value of the weighted sum by 1. This read operation may repeat until the sign of the weighted sum changes from positive to negative. FIG. 15 illustrates an example of positive scanning. In this example, 8-bit data of WC_WL1 to WC_WL8 are encoded as a 3-bit multi-level signal, which corresponds to the output of the sense amplifier SA (i.e., the weighted sum). To distinguish the 8 distinct conductance levels, three successive read operations are performed, each incrementally increasing the number of activated reference cells by one. For example, in the first read operation, reference cell word line RC_WL1 is activated, in the second read operation, reference cell word lines RC_WL1 and RC_WL2 are activated, and in the third read operation, reference cell word lines RC_WL1 to RC_WL3 are activated. For N-bit multi-level signal, the number of successive read operation is (2^{N-1}−1) in the positive scanning to detect that the sign of the output of the sense amplifier transitions from positive to negative. The value of (2^{N-1}−1) is the maximum number of read operations during the positive scanning.

Conversely, to perform negative scanning with negative weight values, the reference cell word line connected to the reference cell pair having a positive reference value must be activated, and the thermometer decoder 220 can control the word line driver 240 to activate the reference cell word line connected to the reference cell pair having a positive reference value. For example, during positive scanning, each read operation performed on the weight cell array WCA and the reference cell array RCA may increase the value of the weighted sum by 1. This read operation may repeat to detect that the sign of the weighted sum changes from negative to positive. FIG. 17 show an example of the negative scanning.

The thermometer decoder 220 can provide a mode signal Sign_MD to the finite state machine FSM. The finite state machine FSM can output an enable signal Sign_EN for stopping the operation of the sense amplifier SA based on a sign signal Sign_SG based on a weighted sum, a mode signal Sign_MD from a thermometer decoder 220, and a previous output signal Sign_PR output from the sense amplifier SA for each read operation.

Since the detailed steps of steps S30 and S40 are substantially the same except for the difference in judging the level of the signal, the following description will be made based on an embodiment in which the sign of the weighted sum of the weight cell array WCA corresponds to a positive number with reference to FIGS. 14 and 15.

The step S30 may include step S300 of setting the value of n to 0 and setting the value of s to 1. Here, the parameter of n may correspond to the number of times the binary counter 230 counts read operations performed on the weight cell array WCA and the reference cell array RCA, and setting the value of n to 0 may correspond to setting the counting number to the initial value 0.

The parameter of s may correspond to the number of reference cell word lines activated by the thermometer decoder 220 based on the counting signal Sign_CT provided from the binary counter 230. For example, when s is 1, the thermometer decoder 220 can control the word line driver 240 to activate only the first reference cell word line RC_WL1, and when s is 2, the thermometer decoder 220 can control the word line driver 240 to activate the first reference cell word line RC_WL1 and the second reference cell word line RC_WL2.

However, the embodiment is not necessarily limited thereto, and the thermometer decoder 220 may activate a number of reference cell word lines other than one reference cell word line each time the value of s increases based on a predetermined value. For example, as described with reference to FIG. 12, the thermometer decoder 220 can activate N reference cell word lines connected to the first reference cell group RCG_1 when s is 1, and can activate a word line connected to one additional reference cell group together with the first reference cell group RCG_1 when s is 2. In this case, the number of reference cell word lines additionally activated by the thermometer decoder 220 each time the value of s increases by 1 can correspond to N.

The step S30 may further include step S310 of determining whether the sign of the weighted sum is positive. As specifically described above, through steps S10 and S20, the sign of the weighted sum of the weight cell array WCA can be stored as the MSB in the flip-flop FF, and the finite state machine FSM can determine whether the sign of the weighted sum is positive based on the value of the MSB stored in the flip-flop FF.

If the sign of the weighted sum is negative N in step S310, step S30 may proceed to step S370 of increasing the value of n until the value of n becomes 2^{N-1}−2. Here, N can mean the number of bits of the weighted sum stored in the flip-flop. If the sign of the weighted sum is negative, the value is converted into multiple bits through step S40, so conversion may not be performed in step S30. In one embodiment, N-bit multi-level sensing may be employed when 2^{N} word lines are selected. As used herein, “N-bit sensing” refers to a sensing scheme in which the read circuitry is capable of distinguishing among 2^{N} discrete levels of cell conductance.

If the sign of the weighted sum is positive Y in step S310, step S30 may proceed to step S320 of performing sequential reference scanning. The sequential reference scanning may proceed to a step of activating the reference cell word line RC_WL based on the determined value of s, and the sense amplifier SA outputs an output signal V_OUT based on a weighted sum based on the weight cell array WCA and a reference value by the activated reference cell word line RC_WL.

Specifically, in FIG. 15, the weighted cell array WCA can have a weighted sum of ‘2’ as described above, and s is set to an initial value of 1 so that only the first reference cell word line RC_WL1 can be activated. Since the reference value of the reference cell pair connected to the first reference cell word line RC_WL1 can be ‘−1’, the arithmetic value based on the weighted sum and the reference value can be ‘1’. Therefore, the sense amplifier SA can output a high level output signal V_OUT based on the arithmetic value ‘1’.

The step S30 may proceed to step S330 of determining whether the level of the output signal is a high level. Specifically, the finite state machine FSM can determine whether the signal level of the output signal V_OUT output from the sense amplifier SA is high.

If the level of the output signal is determined as not a high level in step S330, the process can proceed to step S380 of storing the counting number (i.e., a value of n). Specifically, when the number of reference cell word lines RC_WL activated is sequentially increased by sequentially increasing the value of s, the signal level of the output signal V_OUT may be inverted from a high level to a low level at a specific point in time.

The binary counter 230 can count the number of read operations performed up to that point in time and output it as a counting signal Sign_CT to the flip-flop FF, and the flip-flop FF can store the weighted sum as a plurality of bits based on the counting signal Sign_CT. For example, the flip-flop FF can store a counting signal Sign_CT as its weighted sum. The flip-flop FF can store a counting signal Sign_CT as multiple bits.

After storing the weighted sum as multiple bits through step S380, step S370 can be performed. Specifically, the finite state machine FSM can output an enable signal Sign_EN to stop the operation of the sense amplifier based on determining whether the levels of the mode signal Sign_MD, the sign signal Sign_SG, and the previous output signal Sign_PR are all the same.

For example, the mode signal Sign_MD and the sign signal Sign_SG are maintained at a high level between the third time point T3 and the sixth time point T6, while the level of the immediately preceding output signal Sign_PR may be inverted depending on the magnitude of the weighted sum between the time point T3 and the fourth time point T4, between the fourth time point T4 and the fifth time point T5, and between the fifth time point T5 and the sixth time point T6. In response, the finite state machine FSM can output an enable signal Sign_EN to stop the operation of the sense amplifier SA and output a conversion end signal Sign_CE to the flip-flop FF. In response, the sense amplifier SA can stop its operation, and the flip-flop FF can store the weighted sum as multiple bits based on the counting signal Sign_CT. In an embodiment, the value of the counting signal Sign_CT may correspond to the weighted sum generated by the sense amplifier SA.

The operating method of the memory device according to one embodiment of the present disclosure can reduce overall power consumption because additional operations such as the sense amplifier SA may not be performed when a weighted sum is stored as multiple bits before (2^{N-1}−2) read operations.

On the other hand, if the level of the output signal is a high level in step S330, step S340 of increasing the values of n and s by 1 can be performed. Since the signal level of the output signal V_OUT from the sense amplifier SA is not inverted, the binary counter 230 can increase the value of n by 1, and the thermometer decoder can increase the value of s by 1.

Following step S340, step S350 of determining whether the value of n is (2^{N-1}−2) may be performed. When the value of n is (2^{N-1}−2) in step S350, step S360 of performing the last sequential reference scanning can be performed, whereby the weighted sum can be stored in the flip-flop FF in the form of N bits (S390). If the value of n is not (2^{N-1}−2) in step S350, step S30 may return to step S320 and repeat the steps described above.

Each step S400, . . . , S490 of the operation method of the memory device of FIG. 16 is substantially the same as the steps S300, . . . , S390 of the operation method of the memory device of FIG. 14 except for the step S430 of determining a sign, and therefore, the description of FIGS. 16 and 17 is omitted.

The operating method S30, S40 of a memory device according to one embodiment of the present disclosure can perform a conversion operation of a weighted sum by distinguishing between cases where the sign of the weighted sum is positive and cases where it is negative. For example, the operation methods S30 and S40 of the memory device may perform a conversion operation based on a weighted sum by detecting a transition point at which the sign of the weighted sum changes from positive to negative. Therefore, the configuration of the reference cell array RCA, the sense amplifier SA, and the finite state machine FSM corresponding to a weighted cell array WCA whose weighted sum is negative does not perform any operation while positive scanning is in progress, so that the overall power consumption can be significantly reduced.

FIG. 19 is a block diagram illustrating a memory device according to one embodiment of the present disclosure.

Referring to FIG. 19, the memory device 200 may have an open bit line structure. The memory device 200 may include a first memory cell array MCA_1 and a second memory cell array MCA_2. The first memory cell array MCA_1 may include a first weight cell array WCA_1 and a first reference cell array RCA_1. The second memory cell array MCA_2 may include a second weight cell array WCA_2 and a second reference cell array RCA_2.

A first write driver 240_1 and a first bit line write driver 250_1 for driving the first memory cell array MCA_1 can be connected to the first memory cell array MCA_1. A second write driver 240_2 and a second bit line write driver 250_2 for driving a second memory cell array MCA_2 may be connected to the second memory cell array MCA_2.

The bit line BL and source line SL connected to the first memory cell array MCA_1 can be connected to the first switch box SB1. The bit line BL and source line SL connected to the second memory cell array MCA_2 can be connected to the second switch box SB2. The connection relationship between the first memory cell array MCA_1 and the second memory cell array MCA_2 may change depending on the operation of the first switch box SB1 and the second switch box SB2. The operations of the first switch box SB1 and the second switch SB2 can be controlled by a finite state machine FSM. Specific details are described below.

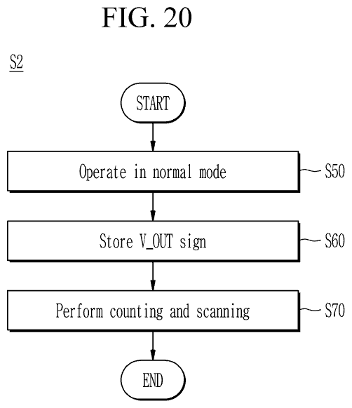

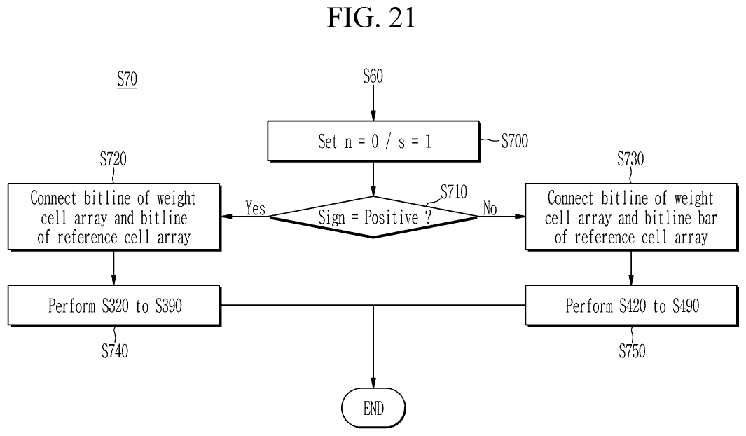

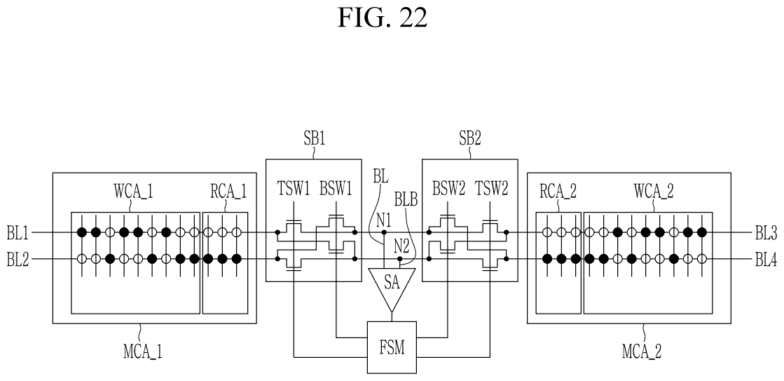

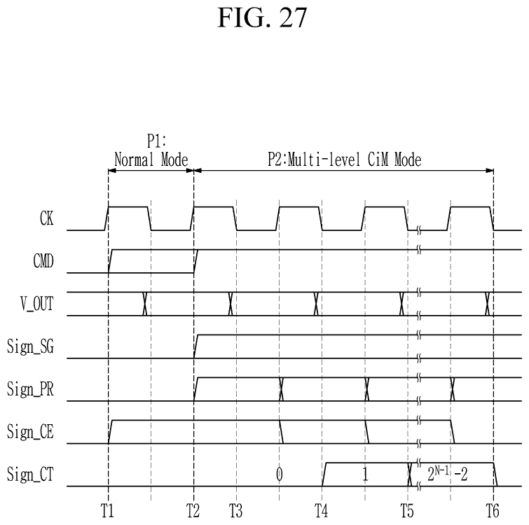

FIG. 20 and FIG. 21 are flowcharts for explaining an operating method of a memory device according to one embodiment of the present disclosure. FIGS. 22 to 26 are drawings for explaining an operating method of a memory device according to one embodiment of the present disclosure. FIG. 27 is a timing diagram for explaining an operating method of a memory device according to one embodiment of the present disclosure.

First, referring to FIG. 22, the first switch box SB1 may include a first top switch TSW1 and a first bottom switch BSW1. The second switch box SB2 may include a second top switch TSW2 and a second bottom switch BSW2. Depending on the operation of the first switch box SB1 and the second switch box SB2, the first bit line BL1 and the second bit line BL2 connected to the first memory cell array MCA_1 can be connected to the third bit line BL3 or the fourth bit line BL4 connected to the second memory cell array MCA_2.

In the open bit line structure, a weight cell array included in a specific memory cell array is connected to a reference cell array included in another memory cell array, so that the above-described reference scanning operation can be performed.

Specifically, the first weight cell array WCA_1 included in the first memory cell array MCA_1 is connected to the second reference cell array RCA_2 included in the second memory cell array MCA_2, so that the above-described reference scanning operation can be performed. The second weight cell array WCA_2 included in the second memory cell array MCA_2 is connected to the first reference cell array RCA_1 included in the first memory cell array MCA_1, so that the above-described reference scanning operation can be performed.

Referring to FIG. 20, the operating method S2 of the memory device may include a step S50 of operating in a normal mode and a step S60 of storing a sign of an output signal. Steps S50 and S60 are substantially the same as steps S10 and S20 described with reference to FIG. 14, respectively, and therefore, a detailed description is omitted.

The operating method S2 of the memory device may include a step S70 of performing counting and scanning operations. The step S70 of performing a counting and scanning operation may include a step of performing positive scanning S30 of FIG. 13 and a step of performing negative scanning S40 of FIG. 13 described with reference to FIG. 13.

Specifically, the step S70 of performing the counting and scanning operation may include the step S700 of setting the value of n to 0 and the step S710 of setting the value of s to 1 and the step of determining whether the sign of the weighted sum is positive. Steps S700 and S710 are substantially the same as steps S300 and S310 described with reference to FIG. 14, respectively, so the following description focuses mainly on the differences.

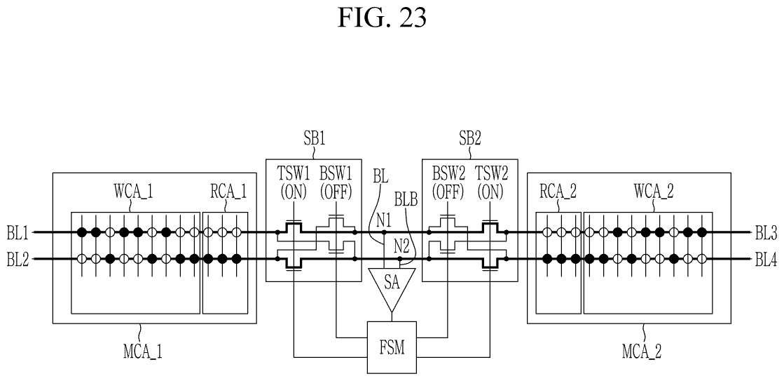

If the sign of the weighted sum is positive Y in step S710 and if the sign of the weighted sum is negative N in step S710, the process can proceed to steps S720 and S730 of connecting the bit lines of the weight cell array and the bit lines of the reference cell array. The connection relationship between the weight cell array and the reference cell array can be variously changed as shown in FIGS. 23 to 26.

First, referring to FIG. 23, when the first top switch TSW1 and the second top switch TSW2 are turned on and the first bottom switch BSW1 and the second bottom switch BSW2 are turned off, the first bit line BL1 connected to the first memory cell array MCA_1 can be connected to the third bit line BL3 connected to the second memory cell array MCA_2, and the second bit line BL2 connected to the first memory cell array MCA_1 can be connected to the fourth bit line BL4 connected to the second memory cell array MCA_2. The first bit line BL1 and the third bit line BL3 can be connected to the sense amplifier SA from the first node N1. The second bit line BL2 and the fourth bit line BL4 can be connected to the sense amplifier SA at the second node N2.

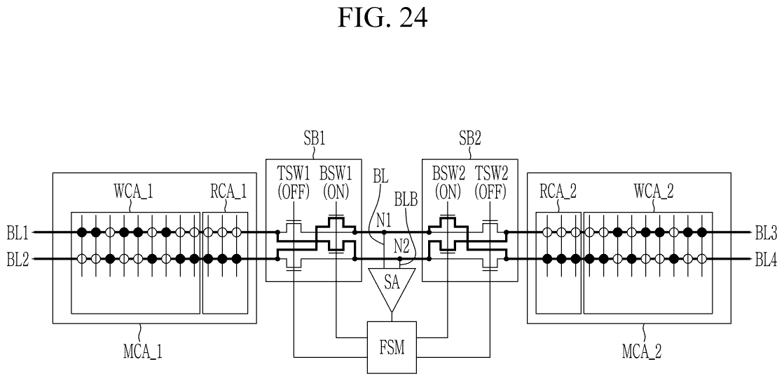

Referring to FIG. 24, when the first bottom switch BSW1 and the second bottom switch BSW2 are turned on and the first top switch TSW1 and the second top switch TSW2 are turned off, the first bit line BL1 connected to the first memory cell array MCA_1 can be connected to the third bit line BL3 connected to the second memory cell array MCA_2, and the second bit line BL2 connected to the first memory cell array MCA_1 can be connected to the fourth bit line BL4 connected to the second memory cell array MCA_2. The first bit line BL1 and the third bit line BL3 can be connected to the sense amplifier SA at the second node N2. The second bit line BL2 and the fourth bit line BL4 can be connected to the sense amplifier SA from the first node N1.

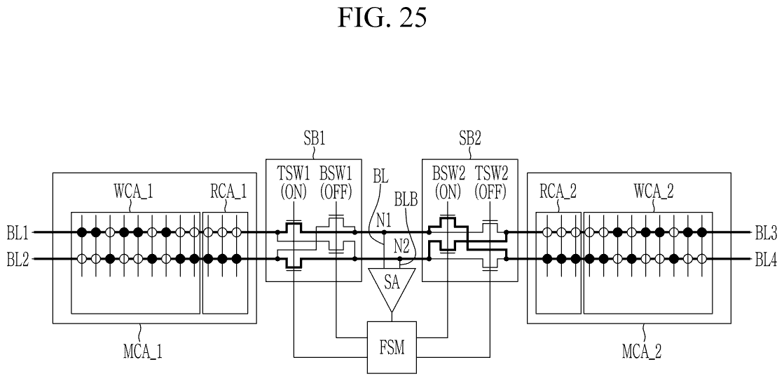

Referring to FIG. 25, when the first top switch TSW1 and the second bottom switch BSW2 are turned on and the first bottom switch BSW1 and the second top switch TSW2 are turned off, the first bit line BL1 connected to the first memory cell array MCA_1 can be connected to the fourth bit line BL4 connected to the second memory cell array MCA_2, and the second bit line BL2 connected to the first memory cell array MCA_1 can be connected to the third bit line BL3 connected to the second memory cell array MCA_2. The first bit line BL1 and the fourth bit line BL4 can be connected to the sense amplifier SA from the first node N1. The second bit line BL2 and the third bit line BL3 can be connected to the sense amplifier SA at the second node N2.

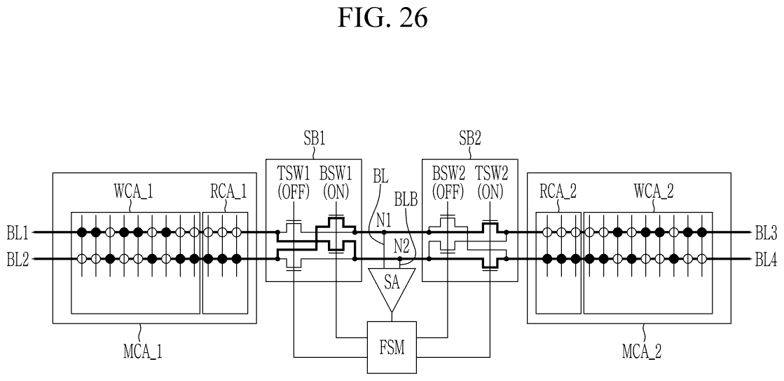

Referring to FIG. 26, when the first bottom switch BSW1 and the second top switch TSW2 are turned on and the first top switch TSW1 and the second bottom switch BSW2 are turned off, the first bit line BL1 connected to the first memory cell array MCA_1 can be connected to the fourth bit line BL4 connected to the second memory cell array MCA_2, and the second bit line BL2 connected to the first memory cell array MCA_1 can be connected to the third bit line BL3 connected to the second memory cell array MCA_2. The first bit line BL1 and the fourth bit line BL4 can be connected to the sense amplifier SA at the second node N2. The second bit line BL2 and the third bit line BL3 can be connected to the sense amplifier SA at the second node N2.

Meanwhile, in some embodiments, when performing reference scanning, only the top switch may be turned on and the bottom switch may be turned off to connect the weight cell array to the sense amplifier SA. For convenience of explanation, the following description will be given as an example of scanning the weighted sum for the first weight cell array WCA_1 using the reference value stored in the second reference cell array RCA_2.

Referring to FIG. 22, in order to output a weighted sum based on the weight values stored in the first weight cell array WCA_1 as an output signal V_OUT, the first top switch TSW1 of the first switch box SB1 can be turned on and the first bottom switch BSW1 can be turned off. In this case, the first bit line BL1 can be connected to the sense amplifier SA through the first node N1, and the second bit line BL2 can be connected to the sense amplifier SA through the second node N2. At this time, the arithmetic value of the weighted sum based on the weight values stored in the first weight cell array WCA_1 may be ‘−1’.

A second reference cell array RCA_2 may be connected to scan a weighted sum for the first weighted cell array WCA_1, and a connection relationship may vary depending on the sign of the weighted sum of the first weighted cell array WCA_1 and the reference value stored in the second reference cell array RCA_2.

As described above, when the first top switch TSW1 is turned on and the first bottom switch BSW1 is turned off, the sign of the weighted sum of the first weight cell array WCA_1 can be negative, and a second reference cell array RCA_2 having a positive reference value can be connected to scan the first weight cell array WCA_1. In the embodiment illustrated in FIG. 22, when a read operation is performed for the second reference cell array RCA_2, the second top switch TSW2 can be turned on and the second bottom switch BSW2 can be turned off so that the third bit line BL3 is connected to the first node N1 and the fourth bit line BL4 is connected.

On the other hand, when the weight values of the reference cell pairs included in the second reference cell array RCA_2 are opposite to the weight values illustrated in FIG. 22, the second top switch TSW2 can be turned off and the second bottom switch BSW2 can be turned on during a read operation for the second reference cell array RCA_2 so that the fourth bit line BL4 is connected to the first node N1 and the third bit line BL3 is connected.

In addition, when the weight values of the weight cell pairs included in the first weight cell array WCA_1 are opposite to the weight values illustrated in FIG. 22, and the first top switch TSW1 is turned on and the first bottom switch BSW1 is turned off, the sign of the weighted sum based on the weight values stored in the first weight cell array WCA_1 can be positive. In this case, a second reference cell array RCA_2 having a negative reference value must be connected to scan the first weight cell array WCA_1. In the embodiment illustrated in FIG. 22, when a read operation is performed for the second reference cell array RCA_2, the second top switch TSW2 can be turned off and the second bottom switch BSW2 can be turned on so that the fourth bit line BL4 is connected to the first node N1 and the third bit line BL3 is connected.

The operating method S70 of the memory device can connect the weight cell array and the reference cell array described above through steps S720 and S730, and then steps S740 and S750 can be performed. For example, step S740 can be performed when the sign of the weighted sum is positive, and step S750 can be performed when the sign of the weighted sum is negative. Steps S740 and S750 are substantially the same as steps S320 to S390 and steps S420 to S490 described with reference to FIG. 14, and therefore, a detailed description thereof is omitted below.

As described above, depending on the sign of the weighted sum based on the weight values stored in the weight cell array, the connection structure of the bit lines connected to the reference cell array can be changed to correspond to the scanning direction. Unlike the operation method S1 of the memory device according to one embodiment of the present disclosure, the operation method S2 of the memory device illustrated in FIG. 13 can simultaneously perform positive scanning and negative scanning, so that the total number of cycles or the total number of counts for converting a weighted sum into a plurality of bits can be reduced by half.

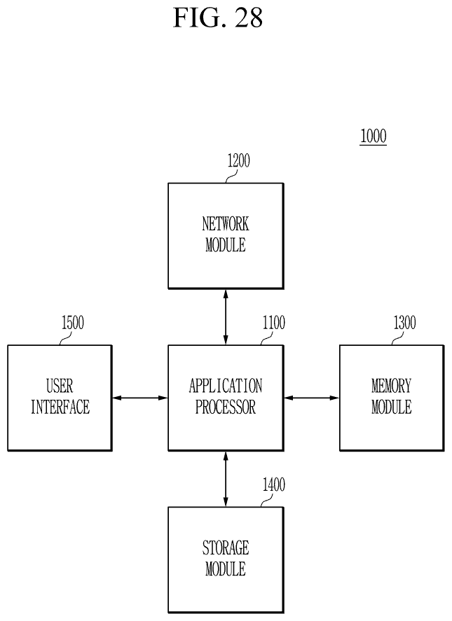

FIG. 28 is a block diagram exemplarily showing a mobile system to which a memory device according to one embodiment of the present disclosure is applied.

Referring to FIG. 28, the mobile system 1000 may include an application processor 1100, a network module 1200, a memory module 1300, a storage module 1400, and a user interface 1500. The application processor 1100 has a configuration corresponding to the host device 100 of FIG. 1, and a detailed description thereof may be replaced with the description of FIG. 1.

The network module 1200 can communicate with external devices. For example, the network module 1200 can support wireless communications such as CDMA Code Division Multiple Access, GSM Global System for Mobile communication, WCDMA wideband CDMA, CDMA-2000, TDMA Time Division Multiple Access, LTE Long Term Evolution, Wimax, WLAN, UWB, Bluetooth, and WI-DI.

The memory module 1300 can operate as a main memory, operating memory, buffer memory, or cache memory of the mobile system 1000. The memory module 1300 may include volatile random access memory such as DRAM, SDRAM, DDR SDRAM, DDR2 SDRAM, DDR3 SDRAM, LPDDR SDARM, LPDDR3, SDRAM, and LPDDR3 SDRAM, or nonvolatile random access memory such as PRAM, ReRAM, MRAM, and FRAM.

The storage module 1400 can store data. For example, the storage module 1400 can store data received from outside. The storage module 1400 can transmit data stored in the storage module 1400 to the application processor 1100. For example, the storage module 1400 may be implemented with a nonvolatile semiconductor memory device such as PRAM, MRAM, RRAM, NAND flash, NOR flash, and a three-dimensional structured NAND flash. For example, the storage module 1400 may be provided as a solid state drive SSD, a multimedia card MMC, an embedded multimedia card eMMC, or a universal flash storage UFS.

The memory module 1300 or storage module 1400 may be implemented as a memory device described with reference to FIGS. 1 to 27.

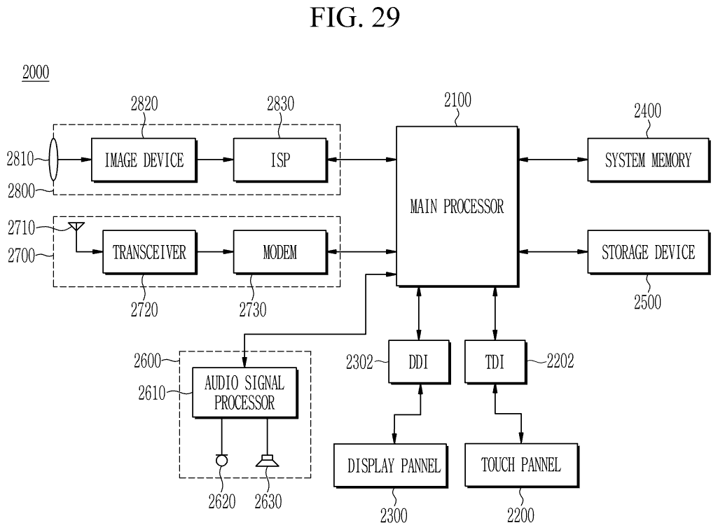

FIG. 29 is a block diagram exemplarily showing an electronic device to which a memory device according to one embodiment of the present disclosure is applied.

Referring to FIG. 29, the electronic device 2000 may include a main processor 2100, a touch panel 2200, a touch driving circuit 2202, a display panel 2300, a display driving circuit 2302, a system memory 2400, a storage device 2500, an audio processor 2600, a communication block 2700, and an image processor 2800. In some embodiments, the electronic device 2000 may be one of various electronic devices, such as a mobile communication terminal, a Personal Digital Assistant PDA, a Portable Media Player PMP, a digital camera, a smart phone, a tablet computer, a laptop computer, and a wearable device.

The main processor 2100 can control the overall operations of the electronic device 2000. The main processor 2100 can control/manage the operations of components of the electronic device 2000. The main processor 2100 can process various operations to operate the electronic device 2000. The touch panel 2200 can be configured to detect touch input from a user under the control of a touch driving circuit 2202. The display panel 2300 can be configured to display image information under the control of the display driving circuit 2302.

The system memory 2400 can store data used for the operation of the electronic device 2000. For example, the system memory 2400 may include volatile memory such as Static Random Access Memory (SRAM), Dynamic RAM (DRAM), and Synchronous DRAM (SDRAM), or nonvolatile memory such as Phase-change RAM (PRAM), Magneto-resistive RAM MRAM, Resistive RAM (ReRAM), and Ferro-electric RAM (FRAM). The storage device 2500 can store data regardless of power supply. For example, the storage device 2500 may include at least one of various non-volatile memories such as flash memory, PRAM, MRAM, ReRAM, and FRAM. For example, the storage device 2500 may include built-in memory and/or removable memory of the electronic device 2000. In some embodiments, the system memory 2400 or storage device 2500 may be implemented as a memory device as described with reference to FIGS. 1 to 27.

The audio processor 2600 can process an audio signal using an audio signal processor 2610. The audio processor 2600 can receive audio input through a microphone 2620 or provide audio output through a speaker 2630. The communication block 2700 can exchange signals with an external device/system through an antenna 2710. The transceiver 2720 and modem 2730 of the communication block 2700 can process signals exchanged with an external device/system according to at least one of various wireless communication protocols, such as LTE Long Term Evolution, WiMax Worldwide Interoperability for Microwave Access, GSM Global System for Mobile communication, CDMA Code Division Multiple Access, Bluetooth, NFC Near Field Communication, Wi-Fi Wireless Fidelity, and RFID Radio Frequency Identification. The image processor 2800 can receive light through the lens 2810. An image device 2820 and an image signal processor 2830 included in the image processor 2800 can generate image information about an external object based on the received light.

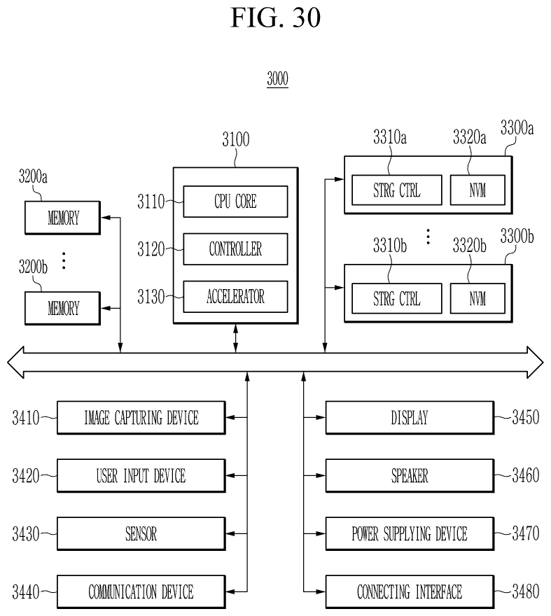

FIG. 30 is a block diagram exemplarily showing a computing system to which a memory device according to one embodiment of the present disclosure is applied.

Referring to FIG. 30, the computing system 3000 may be a mobile system, such as a mobile phone, a smart phone, a tablet personal computer, a wearable device, a healthcare device, and an Internet of Things IoT device. However, the embodiment is not necessarily limited thereto, and the computing system 3000 of FIG. 30 may be a personal computer, a laptop computer, a server, a media player, or an automotive device such as a navigation device.

The computing system 3000 may include a main processor 3100, a memory 3200a, 3200b, and a storage device 3300a, 3300b, and may additionally include one or more of an image capturing device 3410, a user input device 3420, a sensor 3430, a communication device 3440, a display 3450, a speaker 3460, a power supply device 3470, and a connecting interface 3480.

The main processor 3100 can control the overall operation of the computing system 3000, more specifically, the operation of other components that make up the computing system 3000. Such a main processor 3100 may be implemented as a general-purpose processor, a dedicated processor, or an application processor.

The main processor 3100 may include one or more CPU cores 3110 and may further include a controller 3120 for controlling memory 3200a, 3200b and/or storage devices 3300a, 3300b. In some embodiments, the main processor 3100 may further include an accelerator 3130, which is a dedicated circuit for high-speed data operations such as AI Artificial Intelligence data operations. The accelerator 3130 may include a GPU Graphics Processing Unit, an NPU Neural Processing Unit, and/or a DPU Data Processing Unit, and may be implemented as a separate chip that is physically independent from other components of the main processor 3100.

Memory 3200a, 3200b may be used as a main memory device of the computing system 3000 and may include volatile memory such as SRAM and DRAM, but may also include non-volatile memory such as flash memory, MRAM, PRAM, and RRAM. The memory 3200a, 3200b may also be implemented within the same package as the main processor 3100.

The storage device 3300a, 3300b can function as a non-volatile storage device that stores data regardless of whether power is supplied, and can have a relatively large storage capacity compared to the memory 3200a, 3200b. A storage device 3300a, 3300b may include a storage controller 3310a, 3310b and a nonvolatile memory 3320a, 3320b that stores data under the control of the storage controller 3310a, 3310b. The nonvolatile memory 3320a, 3320b may include flash memory of a 2D 2-dimensional structure or a 3D 3-dimensional V-NAND Vertical NAND structure, but may also include other types of nonvolatile memory such as MRAM, PRAM, and RRAM.

The storage device 3300a, 3300b may be included in the computing system 3000 physically separated from the main processor 3100, or may be implemented within the same package as the main processor 3100. In addition, the storage device 3300a, 3300b may have a form such as a solid state device SSD and a memory card, and may be detachably connected to other components of the computing system 3000 through an interface such as a connection interface 3480 to be described later. Such storage devices 3300a, 3300b may be devices to which standard specifications such as UFS Universal Flash Storage, eMMC embedded multi-media card and NVMe non-volatile memory express are applied, but are not necessarily limited thereto. The storage device 3300a, 3300b may include a memory device as described with reference to FIGS. 1 to 27.

The photographing device 3410 can capture still or moving images and may be a camera, a camcorder, and/or a webcam.

The user input device 3420 can receive various types of data input from a user of the computing system 3000, and may be a touch pad, a keypad, a keyboard, a mouse, and/or a microphone.

The sensor 3430 can detect various types of physical quantities that can be obtained from outside the computing system 3000 and convert the detected physical quantities into electrical signals. Such sensors 1430 may be temperature sensors, pressure sensors, light sensors, position sensors, acceleration sensors, biosensors, and/or gyroscope sensors.

The communication device 3440 can transmit and receive signals between other devices outside the computing system 3000 according to various communication protocols. Such a communication device 3440 may be implemented including an antenna, a transceiver, and/or a modem.

The display 3450 and speaker 3460 can function as output devices that output visual information and auditory information, respectively, to a user of the computing system 3000.

The power supply unit 3470 can appropriately convert power supplied from a battery not shown built into the computing system 3000 and/or an external power source and supply it to each component of the computing system 3000.

The connection interface 3480 can provide a connection between the computing system 3000 and an external device that is connected to the computing system 3000 and can exchange data with the computing system 3000. The connection interface 3480 can be implemented in various interface methods such as ATA Advanced Technology Attachment, SATA Serial ATA, e-SATA external SATA, SCSI Small Computer Small Interface, SAS Serial Attached SCSI, PCI Peripheral Component Interconnection, PCIe PCI express, NVMe, IEEE 1394, USB universal serial bus, SD secure digital card, MMC multi-media card, eMMC, UFS, eUFS embedded Universal Flash Storage, and CF compact flash card interface.

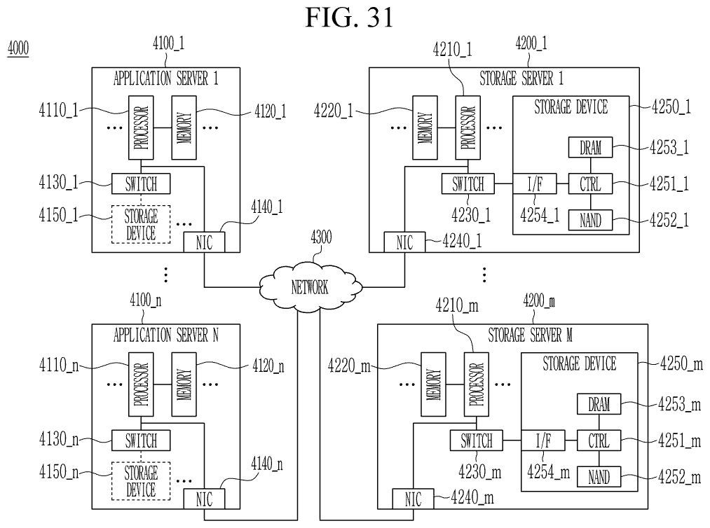

FIG. 31 is a block diagram exemplarily showing a data center to which a memory device according to one embodiment of the present disclosure is applied.

Referring to FIG. 31, a data center 4000 is a facility that collects various types of data and provides services, and may also be referred to as a data storage center. The data center 4000 may be a system for operating a search engine and database, and may be a computing system used by a company such as a bank or a government agency.

The data center 4000 may include application servers 4100_1 to 4100_n and storage servers 4200_1 to 4200_m. The number of application servers 4100_1 to 4100_n and the number of storage servers 4200_1 to 4200_m may be variously selected depending on the embodiment, and the number of application servers 4100_1 to 4100_n and the number of storage servers 4200_1 to 4200_m may be different from each other.

The application server 4100 or storage server 4200 may include at least one of a processor 4110, 4210 and a memory 4120, 4220. Taking the storage server 4200 as an example, the processor 4210 can control the overall operation of the storage server 4200 and access the memory 4220 to execute commands and/or data loaded into the memory 4220. The memory 4220 may be DDR SDRAM Double Data Rate Synchronous DRAM, HBM High Bandwidth Memory, HMC Hybrid Memory Cube, DIMM Dual In-line Memory Module, Optane DIMM, and/or NVMDIMM Non-Volatile DIMM. Depending on the embodiment, the number of processors 4210 and the number of memories 4220 included in the storage server 4200 may be selected in various ways.

In some embodiments, the processor 4210 and memory 4220 may provide a processor-memory pair. In some embodiments, the number of processors 4210 and memories 4220 may be different. The processor 4210 may include a single core processor or a multi-core processor. The above description of the storage server 4200 can be similarly applied to the application server 4100. Depending on the embodiment, the application server 4100 may not include a storage device 4150. The storage server 4200 may include at least one storage device 4250. The number of storage devices 4250 included in the storage server 4200 may be selected in various ways depending on the embodiment. The storage device 4250 may include a memory device as described with reference to FIGS. 1 to 27.

Although the embodiments of the present invention have been described in detail above, the scope of the present invention is not limited thereto, and various modifications and improvements made by those skilled in the art using the basic concept of the present invention defined in the following claims also fall within the scope of the present invention.

What is claimed is:

1. A memory device comprising:
a memory cell array comprising a weight cell array including a plurality of first weight cell pairs and a reference cell array including a plurality of reference cell pairs; and
an analog-to-digital converter (ADC) connected to the plurality of first weight cell pairs and the plurality of reference cell pairs, and configured to output a signal representing a weighted sum of at least one weight value among a plurality of weight values stored in the plurality of first weight cell pairs and at least one reference value among a plurality of reference values stored in the plurality of reference cell pairs in response to activation of at least one corresponding first weight cell word line among a plurality of first weight cell word lines and at least one corresponding reference cell word line among a plurality of reference cell word lines during a read operation,
wherein each weight value of the plurality of weight values has one of a first weight value and a second weight value different from the first weight value, and
wherein each reference value of the plurality of reference values has one of the first weight value and the second weight value.

2. The memory device of claim 1,
wherein each of the plurality of first weight cell pairs includes:
a 1_1 weight cell connected to a first bit line and a first source line, and
a 1_2 weight cell connected to a first complementary bit line complementary to the first bit line and a first complementary source line complementary to the first source line, and
wherein the first bit line and the first complementary bit line are connected to the ADC as inputs.

3. The memory device of claim 2,
wherein each first weight cell pair of the plurality of first weight cell pairs is configured to store a corresponding weight value of the plurality of weight values based on the 1_1 weight cell storing a first value and the 1_2 weight cell storing a second value complementary to the first value.

4. The memory device of claim 2,
wherein each of the plurality of reference cell pairs includes a 1_1 reference cell connected to the first bit line and the first source line and a 1_2 reference cell connected to the first complementary bit line and the first complementary source line.

5. The memory device of claim 4,
wherein the weight cell array further includes a plurality of second weight cell pairs,
wherein the reference cell array is disposed in a space between a first region where the plurality of first weight cell pairs are disposed and a second region where the plurality of second weight cell pairs are disposed, and
wherein the first region, a region where the reference cell array is placed, and the second region are arranged along a direction in which the first bit line extends.

6. The memory device of claim 4, wherein:
wherein each of the 1_1 weight cell, the 1_2 weight cell, the 1_1 reference cell, and the 1_2 reference cell includes a transistor and a magnetic tunnel junction.

7. The memory device of claim 4,
wherein the ADC includes a sense amplifier connected to the first bit line and the first complementary bit line and configured to output the signal representing the weighted sum.

8. The memory device of claim 7,
wherein the ADC further includes a finite state machine (FSM) configured to output an enable signal for stopping an operation of the sense amplifier in response to a sign of the weighted sum transitioning from positive to negative or negative to positive.

9. The memory device of claim 8, further comprising:
a binary counter configured to count a number of the read operation until the sign of the weighted sum transitions from positive to negative or negative to positive and output a counting signal representing the number of the read operation,
wherein the ADC further includes a flip-flop configured to store the number of the read operation counted by the binary counter in a plurality of bits based on the counting signal.

10. The memory device of claim 9,
wherein the finite state machine is configured to provide a conversion end signal to the flip-flop in response to the sign of the weighted sum transitioning from positive to negative or negative to positive, and
wherein the flip-flop is configured to store the counting signal as the weighted sum in response to the conversion end signal.

11. The memory device of claim 9, further comprising:
a thermometer decoder configured to activate N reference cell word lines among the plurality of reference cell word lines at a first time point, and (N+1) reference cell word lines among the plurality of reference cell word lines at a second time point,
wherein the first time point and the second time point are synchronized with the counting signal.

12. The memory device of claim 2,
wherein the memory cell array further includes an offset cell array including an offset cell pair connected to the first source line, the first complementary source line, the first bit line, and the first complementary bit line, and configured to store an offset weight according to a predetermined value.

13. The memory device of claim 1, further comprising:
a control logic circuit configured to:
activate the plurality of reference cell word lines in a unit of A reference cell word lines (A is a positive integer) among the plurality of reference cell word lines in a first time period and in a unit of B reference cell word lines (B is a positive integer different from A) in a second time period different from the first time period.

14. The memory device of claim 1, further comprising:
a control logic circuit configured to:
control M (M is a positive integer) reference cell pairs among the plurality of reference cell pairs to be stored in a first weight in a first time period; and
control the M reference cell pairs to be stored in a second weight different from the first weight in a second time period different from the first time period.

15. A memory device comprising:
a memory cell array including a weight cell array configured to store a plurality of weight values and a reference cell array configured to store a plurality of reference values;
a sense amplifier configured to output an output signal based on the plurality of weight values and the plurality of reference values;
a thermometer decoder configured to control a sequence of activating a plurality of word lines connected to the reference cell array based on a mode signal to determine when a level of the output signal is inverted;
a binary counter configured to count a number of clocks until the level of the output signal is inverted and output a counting signal; and
a flip-flop configured to store a weighted sum as a plurality of bits calculated based on the plurality of weight values based on the counting signal.

16. The memory device of claim 15, further comprising:
a finite state machine configured to output an enable signal for stopping an operation of the sense amplifier based on determining whether a level of a sign signal of the weighted sum, a level of the mode signal of the thermometer decoder, and a level of the output signal are equal.

17. The memory device of claim 15,
wherein a sign signal of the weighted sum is stored in the flip-flop as the most significant bit (MSB) among the plurality of bits.

18. A method of operating a memory device comprising:
a step of outputting a first weighted sum of a plurality of weight values stored in a plurality of weight cell pairs;
a step of storing a sign of the first weighted sum in a flip-flop based on a signal level of the first weighted sum, wherein the sign of the first weighted sum is positive or negative;
a step of performing reference scanning for a second weighted sum based on the sign of the first weighted sum by performing a read operation on both the plurality of weight cell pairs and a plurality of reference cell pairs storing a plurality of reference values, wherein the read operation is successively performed by increasing a number of reference cell pairs, among the plurality of reference cell pairs, which are activated;
a step of determining the signal level of the second weighted sum in response to a sign of the second weighted sum changes from positive to negative or negative to positive;
a step of outputting a counting signal of a binary counter, wherein the counting signal represents a number of the read operation successively performed; and
a step of storing the second weighted sum as a plurality of bits in the flip-flop based on the counting signal, when the sign of the second weighted sum transitions positive to negative or negative to positive and a number of times the reference scanning is performed satisfy a predetermined condition.

19. The method of operating the memory device of claim 18,
wherein the step of performing the reference scanning for the second weighted sum comprises:
a step of performing the reference scanning for the plurality of weight cell pairs in which the sign of the second weighted sum is positive in a first time period; and
a step of performing the reference scanning for the plurality of weight cell pairs in which the sign of the second weighted sum is negative in a second time period subsequent to the first time period.

20. The method of operating the memory device of claim 18,
wherein the step of performing the reference scanning for the second weighted sum comprises:
a step of connecting the plurality of weight cell pairs in which the sign of the second weighted sum is positive and the plurality of reference cell pairs storing a negative reference value;
a step of connecting the plurality of weight cell pairs in which the sign of the second weighted sum is negative and the plurality of reference cell pairs storing a positive reference value; and
a step of simultaneously performing the reference scanning on the plurality of weight cell pairs in which the sign of the second weighted sum is positive and the plurality of weight cell pairs in which the sign of the second weighted sum is negative.
